(19) United States
(12) Patent Application Publication
(10) Pub. No.: US 2010/0294349 A1
(43) Pub. Date: Nov. 25, 2010

(54) BACK CONTACT SOLAR CELLS WITH EFFECTIVE AND EFFICIENT DESIGNS AND CORRESPONDING PATTERNING PROCESSES

(76) Inventors: Uma Srinivasan, Mountain View, CA (US); Xin Zhou, San Jose, CA (US); Henry Hieslmair, San Francisco, CA (US); Neeraj Pakala, Cupertino, CA (US)

Correspondence Address: DARDI & HERBERT, PLLC, Moore Lake Plaza, Suite 205, 1250 East Moore Lake Drive, Fridley, MN, 55432, US

(21) Appl. No.: 12/469,441

(22) Filed: May 20, 2009

(51) Int. Cl. H01L 31/00; H01L 21/26

(52) U.S. Cl. 136/255; 438/535; 257/E21.328

(57) ABSTRACT

Laser based processes are used alone or in combination to effectively process doped domains for semiconductors and/or current harvesting structures. For example, dopants can be driven into a silicon/germanium semiconductor layer from a bare silicon/germanium surface using a laser beam. Deep contacts have been found to be effective for producing efficient solar cells. Dielectric layers can be effectively patterned to provide for selected contact between the current collectors and the doped domains along the semiconductor surface. Rapid processing approaches are suitable for efficient production processes.

### FIELD OF THE INVENTION

The invention relates to solar cells having both polarities of doped contacts along the rear or back side of the cell. The doped contacts are patterned to provide effective collection of the photocurrent. Efficient processing approaches provide for formation of the doped contacts along selected patterns for back contact solar cells as well as other solar cell designs.

### BACKGROUND OF THE INVENTION

Photovoltaic cells operate through the absorption of light to form electron-hole pairs. A semiconductor material can be conveniently used to absorb the light with a resulting charge separation. The photocurrent is harvested at a voltage differential to perform useful work in an external circuit, either directly or following storage with an appropriate energy storage device.

Various technologies are available for the formation of photovoltaic cells, e.g., solar cells, in which a semiconducting material functions as a photoconductor. A majority of commercial photovoltaic cells are based on silicon. With non-renewable energy sources continuing to be less desirable due to environmental and cost concerns, there is continuing interest in alternative energy sources, especially renewable energy sources. Increased commercialization of renewable energy sources relies on increasing cost effectiveness through lower costs per energy unit, which can be achieved through improved efficiency of the energy source and/or through cost reduction for materials and processing. Thus, for a photovoltaic cell, commercial advantages can result from increased energy conversion efficiency for a given light fluence and/or from lower cost of producing a cell.

### SUMMARY OF THE INVENTION

In a first aspect, the invention pertains to a photovoltaic cell comprising a semiconductor layer, an n-doped domain and a p-doped domain along a surface of the semiconductor layer at the same level as each other. In some embodiments, the doped domains each have an average depth from about 100 nm to about 5 microns and an edge-to-edge spacing between the n-doped domain and the p-doped domain has a value at one or more locations from about 10 microns and about 500 microns.

In a further aspect, the invention pertains to a photovoltaic cell comprising a semiconductor layer, an n-doped domain and a p-doped domain along a surface of the semiconductor layer at the same level as each other. In some embodiments, the doped domains each have a planar extent along the surface comprising a stripe having a ratio of the average length that is at least about a factor of 10 greater than the average width and a spacing between the n-doped domain and the p-doped domain has a value at one or more locations from about 10 microns and about 500 microns.

In additional aspects, the invention pertains to a photovoltaic cell comprising a semiconductor layer, an n-doped domain and a p-doped domain along a surface of the semiconductor layer. The doped domains can each have a planar extent along the surface comprising a stripe having a ratio of the average length that is at least about a factor of 10 greater than the average width, a dielectric layer over the doped domains and a plurality of patterned metal interconnects. The dielectric layer can comprise windows that expose from about 5 percent to about 80 percent of each of the doped domains, and the metal interconnects over the windows with the metal interconnects can have an area at least about 20 percent greater than the area of the windows.

In other aspects, the invention pertains to a method for doping a semiconductor along a selected pattern, the method comprising pulsing an energy beam at a plurality of selected locations along a surface to drive a first dopant from a dopant source into a semiconductor layer at the selected location to form a first doped domain. In some embodiments, the dopant source is formed in a layer substantially covering the semiconductor layer. The method can further comprise removing the first dopant source, and depositing a second dopant source comprising a second dopant to substantially cover the semiconductor layer. The method also can further comprise pulsing an energy beam at a plurality of selected locations along a surface to drive the second dopant into a semiconductor layer at the selected location to form a second doped domain.

Moreover, the invention pertains to a method for selectively etching openings through an inorganic layer, the method comprises patterning a layer of polymeric etch resist and performing an etch to form windows through the inorganic layer. In some embodiments, the patterning of a layer of polymeric etch resist is performed by ablating the polymer using an energy beam at a plurality of selected locations to remove the etch resist at the selected locations.

Additionally, the invention pertains to a method for forming a semiconductor based device. Generally, the method comprises forming doped domains onto a first surface of a Si semiconductor foil, depositing an inorganic dielectric layer onto the first surface covering the doped domains, and patterning a metal current collector on the dielectric layer. The Si semiconductor foil can have an average thickness of from about 5 microns to about 100 microns. The semiconductor foil has a first surface and a second surface opposite the first surface, and the second surface of the semiconductor foil is adhered to a glass structure with a polymer, such as an adhesive. Portions of the metal current collector can make contacts with the doped domains through the dielectric layer. In some embodiments, the processing steps do not heat the adhesive to a temperature greater than about 200° C.

In further embodiments, the invention pertains to a photovoltaic cell comprising a semiconductor layer, an n-doped domain and a p-doped domain along a surface of the semiconductor layer. The doped domains can each have a planar extent along the surface comprising a stripe having a ratio of the average length that is at least about a factor of 10 greater than the average width. In some embodiments, one or more enhanced dopant sections of the stripe have an average surface dopant concentration that is at least about 5 times the average dopant concentration at other locations of the n-doped domain.

Furthermore, the invention pertains to a photovoltaic cell comprising a semiconductor layer, a plurality of n-doped domains and a plurality of p-doped domains along a surface of the semiconductor layer. The doped domains can have an average depth from about 250 nm to about 2.5 microns, and the top 10% of the thickness of the contact can have an average dopant concentration that is at least a factor of 5 greater than the average dopant concentration for the contact at the level at the 20-30% of the contact depth from the top of the contact.

In other embodiments, the invention pertains to a photovoltaic cell comprising a semiconductor layer, a plurality of n-doped domains along a surface of the semiconductor layer, a plurality of p-doped domains along the surface of the semiconductor layer, a dielectric layer, a first current collector in electrical connection with the n-doped domains, and a second current collector in electrical contact with the p-doped domains. The dielectric layer can comprise an inorganic layer along the surface of the semiconductor layer and a polymer layer on the inorganic layer with the current collectors covering a portion of the polymer layer. The respective current collectors can contact the corresponding doped domain through windows through the dielectric layer.

In addition, the invention pertains to a method for doping a semiconductor layer, the method comprising:

patterning a plurality of dopant sources along a bare semiconductor layer comprising silicon to form a patterned semiconductor layer; and

scanning a light beam across the patterned semiconductor layer to drive dopant from the dopant sources into the semiconductor layer to form a plurality of n-doped domains and a plurality of p-doped domains.

### BRIEF DESCRIPTION OF THE DRAWINGS

FIG. 1 is a schematic perspective view of a solar cell.

FIG. 2 is a sectional side view of the solar cell of FIG. 1.

FIG. 3 is a schematic fragmentary perspective view of a photovoltaic module with a portion of a backing material removed to expose the rear of some of the solar cells mounted within the module.

FIG. 4 is a sectional view of the photovoltaic module of FIG. 3.

FIG. 5 is a plot of 6 different laser pulse waveforms as a function of time.

FIG. 6 is a plot of SIMS measurements of a dopant profile for a boron doped contact formed in a silicon wafer with infrared laser doping.

FIG. 7 is a plot of SIMS measurements of a dopant profile for a phosphorous doped contact formed in a silicon wafer with infrared laser doping.

FIG. 8 is a plot of a Spreading Resistance Profile (SRP) measurement of dopant profile for a phosphorous doped contact in a silicon wafer formed with infrared laser doping.

FIG. 9 is a plot of sheet resistance of a doped contact formed by infrared laser doping, where the resistance is plotted as a function of infrared laser fluence for three different laser pulse frequencies.

FIG. 10 is a plot of surface roughness of a doped contact formed by infrared laser doping, where the resistance is plotted as a function of infrared laser fluence for three different laser pulse frequencies.

FIG. 11 is a collection of five photographs of a wafer surface following a laser doping step where in the individual photographs are for five different laser scanning rates at a particular laser pulse frequency.

FIG. 12 is a collection of five photographs of a wafer surface following a laser doping step where in the individual photographs are for five different laser scanning rates at a particular laser pulse frequency and where the laser pulse frequency used for the processing in FIG. 12 is different from the laser pulse frequency used to obtain the photographs in FIG. 11.

FIG. 13 is a photograph showing a top surface of a wafer with a trench cut through a silicon oxide dielectric layer in which the etching is performed following laser ablation of a polymer etch resist.

FIG. 14A is a photograph of the top surface of a wafer with windows ablated through a silicon nitride dielectric layer with a laser.

FIG. 14B is an enlarged photograph of two windows of FIG. 14A where exposed silicon is visible below the silicon nitride dielectric layer.

FIG. 15 is a photograph of the top surface of a wafer with a trench etched through an aluminum layer in which the etching is performed following laser ablation of a polymer etch resist.

FIG. 16 is a photograph of a top view of a trench pattern cut through a metal layer based on an etching performed following alloying of two layers of metal.

FIG. 17 is a photograph with an enlarged view of a trench pattern cut through a metal coating in which the etching is performed after three passes of a laser beam over the pattern to form an alloy between two metal layers that enables selective etching.

FIG. 18 is a plot of diode performance of an embodiment of a solar cell without illumination.

FIG. 19 is plot of solar cell performance based on current density and efficiency for the embodiment of the solar cell described with reference to FIG. 18 under illumination with a one sun condition.

FIG. 20 is a plot of solar cell performance based on current density and efficiency for an alternative embodiment of a solar cell under illumination with a one sun condition.

### DETAILED DESCRIPTION OF THE INVENTION

Back contact solar cell designs take advantage of improved processing approaches to provide effective contact designs with corresponding excellent performance of the cells. In some embodiments, spaced apart stripes of different doped domains are designed for efficient cell performance and rapid processing. The spacing between adjacent doped domains, the depth of the dopant and the area of the doped domains can be selected to provide desired cell performance based on commercially practical processes. A light beam can be scanned across a semiconductor surface to drive in a dopant into the semiconductor at selected locations. N-type dopants and p-type dopants can be sequentially deposited or simultaneously deposited. An effective metal patterning approach can be used to form current collectors for the two poles of the cell with selected patterns generally along a single level with a dielectric layer over the semiconductor material. The processing approaches described herein can be effectively used for the simultaneous processing of a plurality of photovoltaic cells, such as within a module.

Alternative effective approaches are described for the formation of electrical connections between the metal current collectors and doped contacts along the semiconductor material through a passivation, e.g., dielectric, layer. In some embodiments, a windowed dielectric layer can also be effectively formed over the doped semiconductor material to provide for appropriate electrical connectivity to the doped contacts to harvest the photocurrent. Efficient methods provide for the patterning of the dielectric based on laser patterning with an etching step according to the pattern of the doped contacts, as well as for the patterning of the electrical interconnects to provide for current collection. In some embodiments, the dielectric layer is directed ablated in a soft ablation step to form windows through the dielectric layer without significantly damaging the underlying silicon material. Laser ablation of a dielectric layer is described further in an article to Prue et al., entitled “Laser Ablation—A new Low-Cost Approach for Passivated Rear Contact Formation in Crystalline Silicon Solar Cell Technology,” 16th European Photovoltaic Solar Energy Conference, May 2000, incorporated herein by reference. In alternative or additional embodiments, a laser is used to directly drive the electrical connection between patterned metal and doped contact through the dielectric layer that results in very good electrical connection between the metal and the doped contacts. Laser-fired contacts are described further for solar cell formation in U.S. Pat. No. 6,982,218 to Prue et al., entitles “Method of Producing a Semiconductor-Metal Contact Through a Dielectric Layer,” incorporated herein by reference.

The improved processes described herein provide for the efficient and cost effective formation of back contact solar cell designs that provide for efficient harvesting of the photocurrent. The processing steps can also be used for the formation of desired structures on other solar cell designs in addition to back contact cell designs, such as cells with doped contacts along the front surface of the cell.

Photovoltaic modules generally comprise a transparent front sheet that is exposed to light, generally sunlight, during use of the module. One or more solar cells, i.e., photovoltaic cells, within the photovoltaic module can be placed adjacent to the transparent front sheet such that light transmitted through the transparent front sheet can be absorbed by a semiconductor material in the solar cell. The cells of the module can be simultaneously processed using the approaches described herein. The transparent front sheet can provide support, physical protection as well as protection from environmental contaminants and the like. The active material of a photovoltaic cell is generally a semiconductor. Following absorption of light, photocurrent can be harvested from the conduction band to perform useful work through connection to an external circuit. For a photovoltaic cell, improved performance can be related to increased energy conversion efficiency for a given light fluence and/or to lowering the cost of producing a cell.

The semiconductor can be lightly doped to increase electron mobilities of the semiconductor material. Regions with increased dopant concentrations, called doped contacts, interfacing with the semiconductor material facilitate the harvesting of the photocurrent. In particular, electrons and holes can segregate to the respective n-doped and p-doped regions. The doped contact regions interface with electrical conductors that form current collectors to harvest the photocurrent formed by absorbing light to generate a potential between the two poles of the contacts. Within a single cell, the doped contact regions of like polarity can be connected to a common current collector such that the two current collectors associated with the different polarity of doped contacts form the counter electrodes of the photovoltaic cell.

In embodiments of particular interest, the photovoltaic module comprises a silicon, germanium or silicon-germanium alloy material that is used for the semiconductor sheet. For simplicity of discussion, the reference herein to silicon implicitly refers to silicon, germanium, silicon-germanium alloys and blends thereof, unless indicated otherwise in context. In some embodiments, silicon is a desirable material due to its relatively low cost. In the claims, silicon/germanium refers to silicon, germanium, silicon-germanium alloys and blends thereof, while either element separate refers solely to that element. The semiconductor sheets generally can be doped, although the overall dopant concentrations across the semiconductor layer are less than the dopant concentrations of appropriate corresponding doped contacts. In the following, embodiments of solar cells and processes based on polycrystalline silicon are discussed in more detail, although appropriate portions can be generalized for other semiconductor systems based on the disclosure herein. Furthermore, thin silicon foils can be suitable for processing approaches herein in which, in some embodiments, the foils can have a thickness form about 5 microns to about 100 microns. The formation of large area thin silicon foils is made possible as a result of revolutionary process approaches.

The placement and properties of dopant contact regions within a cell influences performance of a cell. In particular, the depth of doped contacts along with the spacing of p-doped regions with respect to n-doped regions can influence cell performance. Similarly, the area attributed to doped contact regions, i.e., p-doped and n-doped regions influences cell performance. The processing approach generally can also influence the placement and size of the doped regions at least with respect to available ranges. As described herein, the properties of the doped contacts have been selected to achieve excellent current generation efficiency of an individual cell using convenient processing approaches.

While back contact solar cells are of particular interest, some processing approaches herein are convenient for elements for other cell designs. In some embodiments, the solar cells have one pole of dopants across the front face of the cell and the opposite pole of dopants across the back of the cell. In these embodiments, the current collector along the front of the cell is directed from the front of the cell to the side or rear for connection to external circuits. The current collector along the front of the cell should be placed for effective current collection without excessive amount of metal since the metal along the front of the cell blocks light from entering the semiconductor such that cell efficiency is reduced somewhat. Solar cell embodiments in which current collectors are placed along both the front and rear surfaces of the solar cell are described further in U.S. Pat. No. 6,093,882 to Arimoto, entitled “Method of Producing a Solar Cell; a Solar Cell and a Method of Producing a Semiconductor Device,” and U.S. Pat. No. 5,082,791 to Micheels et al., entitled “Method of Fabricating Solar Cells,” both of which are incorporated herein by reference.

In embodiments of particular interest, the doped contacts are all placed on the rear or back side of the solar cell so that no current collectors are placed on the front surface of the cell. Basic back contact solar cell designs have been known for some time. For example, some designs are described in U.S. Pat. No. 4,133,698 to Chiang et al., entitled “Tandem Junction Solar Cell,” and U.S. Pat. No. 4,478,879 to Baraoan et al., entitled “Screen Printed Interdigitated Back Contact Solar Cell,” both of which are incorporated herein by reference. The improved processing approaches described herein are particularly suitable for the formation of efficient designs for back contact solar cells. Furthermore, the introduction of a silicon foil for the semiconductor material further provides for conservation of silicon material, and the processing approaches are also suitable for use with large area formats that can be obtained with silicon foils.

In some embodiments, the doped contacts are distributed across the back surface of the semiconductor, and the placement and properties of the doped contacts influence the performance and efficiency of the solar cell. In general, it is advantageous to distribute a plurality of contacts of each dopant type across the surface in an alternating fashion. The doped contacts provide for the harvesting of the photocurrent, but electron-hole recombination can also take place at doped contacts, which can lower cell efficiency. Thus, there can be a balance of factors.

In general, the doped domains can be laid out as islands or regions that alternate across the surface. The layout can be similar to a checkerboard pattern, although the regions do not have to be the same size and the pattern does not have to be along a rectangular grid. The doped contact regions can be square, round, oval, rectangular or other convenient shape or combinations thereof.

It has been discovered that linear stripes of spaced apart dopant domains can be efficiently formed while providing excellent cell performance. In particular, the stripes can have large aspect ratios so that the stripes can have relatively large lengths with narrow widths. Generally, the aspect ratio of the length divided by the width is at least 10. In particular, the widths are generally from about 20 microns to about 500 microns. The edge-to-edge spacing between the two dopant domains can be from about 5 microns to about 500 microns at least one point of approach between adjacent dopant domains. The lines of dopant contacts can integrate into more complex patterns with bends, corners and the like. However, in some embodiments, linear segments form a significant portion of the structures.

The depth of the dopant penetration also influences cell performance. If the adjacent dopant domains are spaced apart an appropriate distance, moderately deep dopant domains can be used without observing undesirable levels of back recombination that can diminish the photocurrent. In conjunction with the desire to form dopant domains with these depths, suitable processing approaches have been found to efficiently form moderately deep dopant contacts, as described further below. In some embodiments, a plurality of dopant contacts has an average depth from about 100 nm to about 5 microns. Through the combination of doped contact features described herein very efficient processing can effectively be used to make solar cells with desirable levels of performance.

In some embodiments, the dopant profile can have a specifically engineered non-uniform distribution. For example, performance can be improved with a higher dopant concentration near the surface of the doped region such that conduction of the photocurrent is improved without resulting in an undesirable level of recombination. Similarly, a doped stripe can have a shallower dopant distribution in the interior of the stripe relative to the edges to similarly provide improved conduction to the current collectors without increasing recombination to an undesirable degree.

The doped contacts connect with current collectors to complete the harvesting of the photocurrent. Generally, a solar cell comprises two current collectors of opposite polarity, although a solar cell can comprise a greater number of current collectors with the same polarity, for example, if the same polarity current collectors appropriately connected in series, which effectively combines the individual current collectors into a single current collector of each polarity by way of external connections. The current collectors for the opposite poles are electrically isolated to prevent short circuiting of the solar cell. Furthermore, it can be desirable to have a dielectric passivation layer on both sides of the semiconductor material. The current collector can penetrate past the passivation layer to connect with the doped contacts.

A current collector extends over a selected pattern on the surface aligned with the doped domain(s) of a particular polarity. Two distinct processes are described herein for connecting the metal interconnect with the appropriate doped contact. In either case, it has been found to be desirable to select the area of contact between the current collectors and the doped contacts to cover only a portion of the area of the doped contact. The windows and holes in the dielectric layer are selected for appropriate connection between the current collectors and the doped contacts to provide appropriate connectivity and low electrical resistance. In general, the windows or holes through the back dielectric layer cover a selected fraction of the doped contact area, generally from about 5 percent to about 80 percent of the area of the doped domains.

Similarly, the current collectors generally have a greater area than the windows or holes through the passivation layer. In general, the current collectors of a particular polarity can have an area at least about 20 percent greater than the windows or holes that are covered by the current collector. Also, selection of a window or hole size for a particular processing approach can be based on avoiding any significant overlap of the window with any areas of the semiconductor away from the doped domains since such overlap can result in an electrical shunt from contact with the current collector that can reduce cell performance. Furthermore, a modest amount of area of electrical connection can provide sufficient electrical current at an appropriately low resistance with the doped contacts with the formats described herein for the doped contacts.

For many applications, a plurality of solar cells is mounted within a module. Generally, the solar cells in a module are electrically connected in series to increase the voltage of the module, although the cells or a portion thereof can be connected in parallel. The solar cells of a module can be assembled with appropriate structural supports, electrical connections and seals to keep out moisture and other environmental assaults. In some embodiments, a module can be assembled from a single sheet of silicon foil. The contacts for the cells can be patterned along the back surface of the foil, and the foil can be cut prior to or following patterning to separate the individual cells. The cutting of the cells for a module from a single sheet of silicon foil can provides for more consistent performance of the cells within the module, which improves overall efficiency of the module if the cells are better matched with each other. However, in some embodiments, individual sections of semiconductor, e.g., thin sheets of semiconductor, can be assembled on a transparent substrate for subsequent processing into an array of solar cells using one or more of the processing approaches described herein.

Improved processes described herein focus on the back side processing of the cell to provide for harvesting of the photocurrent. For back contact solar cells, the front surface of the solar cell can be subjected to separate processing, for example, to apply a texture, to form a passivating dielectric layer, and/or to secure the front surface of the cell to a transparent substrate. Improved processes for the formation of doped contacts and current collectors associated with these contacts with a dielectric material covering portions of the back surface provide the capabilities for forming the improved back contact solar cells described herein.

In general, the improved processing approaches described herein provide relatively rapid and efficient processes for the formation of the solar cell structures described herein. Several of the processing steps can involve energy beams, such as laser beams, that are scanned over the surface. These scanning approaches provide for the formation of relatively intricate patterns at moderate resolution along with fast processing speed and moderate cost. Furthermore, the approaches can be performed dynamically if desired to achieve further improved performance. For example, the dynamic division of a silicon foil for the formation of a plurality of solar cells is described further in published U.S. patent application 2008/0202577 to Hieslmair, entitled “Dynamic Design of Solar Cell Structures, Photovoltaic Modules and Corresponding Processes,” incorporated herein by reference.

A process has been developed that has eliminated material patterning to form the doped contacts. In particular, a dopant source can be spread over the whole surface or area thereof. Suitable dopant sources include, for example, spin on glass compositions with appropriate dopant elements, although other suitable dopant sources are described further below. A laser, such as an infrared laser, is then scanned across the surface according to a selected pattern to drive the dopant into the semiconductor layer. Infrared lasers are a convenient energy sources since the infrared light penetrates to desired depths into the silicon to heat the silicon and drive the dopants into the silicon at a depth based on the processing parameters. Also, commercial infrared lasers are available in appropriate scanning systems at reasonable costs. As a result of the penetration depth of the laser, the laser power can be correspondingly selected to melt a localized portion of the silicon to drive the dopant through the heated depth of the silicon. Thus, a relatively deep but well localized doped contact can be efficiently formed. The pulsing of the laser can be timed with the scanning speed to provide an appropriate distance between laser spots to obtain the desired amount of dopant drive in. The laser can be scanned along a line to form a contact with a selected area.

In some embodiments, after the drive in of one dopant, the semiconductor surface can be cleaned of the first dopant composition, and a second dopant composition can be coated over the surface or a portion thereof. Then, the laser dopant drive in can be repeated for the second dopant. After the second dopant is driven into the semiconductor material, the second dopant source can be removed from the semiconductor. In some embodiments, the second dopant is driven into the semiconductor at spaced apart locations relative to the first dopant locations. Additionally or alternatively, the dopant drive in steps for each dopant type can be repeated at approximately the same location to provide additional control over the dopant amount and profile.

In further embodiments, the dopant sources can be printed onto the semiconductor surface, such as with inkjet printing, screen printing or the like. In this way, a pattern of p-dopant source and n-dopant source can be printed across the semiconductor surface with separate domains with different dopants. The dopant drive in, such as with a scanned laser beam, can be similarly performed except that the doped contacts for both n-dopants and p-dopants can be formed during a single scanning step. The patterning of the dopant sources results in the proper dopant deposition within the doped domains. In this way, the formation of both doped contacts can be performed in a single step without cleaning the surface after delivering a first dopant. The surface can be cleaned following the drive in for both dopants. While both dopants can be deposited into doped contacts in a single processing step, the dopant deposition process with printed dopant sources can be repeated if desired to alter the dopant profiles.

The spacing between the dopant locations can be selected to form a desired pattern of doped contacts. For example, a first dopant can be deposited along a rough line and the second dopant can be deposited along an approximately parallel line. An average spacing between adjacent doped contacts can be selected for the separation between the lines. It has been found that good performance of the solar cell can be obtained with appropriate spacing between the adjacent doped contacts.

Generally, a passivation layer is deposited over the semiconductor layer after forming the doped contacts. The passivation layer protects the semiconductor layer and generally is formed of a dielectric material that forms an electrically insulating layer along the surface. The passivation material on the semiconductor can comprise a plurality of distinct dielectric layers. Suitable dielectric materials to form passivation layers include, for example, stoichiometric and non stoichiometric silicon oxides, silicon nitrides, and silicon oxynitrides, with or without hydrogen additions. Specifically, passivation layers can comprise, for example, SiNₓO_{y}, x≦4/3 and y≦2, silicon oxide (SiO₂), silicon nitride (Si₃N₄), silicon rich oxide (SiOₓ, x<2), or silicon rich nitride (SiNₓ, x<4/3). The dielectric layer or a portion thereof can comprise a polymer, such as a suitable organic polymer, which can have desirable electrical insulation properties. These passivation layers protect the semiconductor material from environmental degradation, reduce surface recombination of holes and electrons As noted above, metal or other electrically conducting material connects to the doped semiconductor regions as a current collector within a cell. The current collectors of adjacent cells can be joined with electrical connections to connect the cells in series. The end cells in the series can be connected to an outside circuit to power selected applications or to charge an electrical storage device, such as a rechargeable battery. The photovoltaic module can be mounted on a suitable frame.

Three efficient ways can be used to provide for electrical connections between the current collector through the dielectric passivation layer. Each of these techniques make use of laser processing for fast and relatively precise placement of the connections at the relevant moderate resolutions. In a first method, patterning is performed with an etching step. A polymer photoresist is placed over the dielectric surface. The laser at relatively low power is used to ablate the polymer at a selected pattern. The etching is then performed to remove the dielectric at locations where the photoresist has been removed. The selective etching leaves the silicon intact. In this way, windows are made through the dielectric. The windows are aligned during the patterning to be at locations of the doped contacts so that they provide the basis for the electrical connection to the doped contacts. After the etching is performed, the remaining polymer photoresist can be stripped off of the dielectric layer. Alternatively, the polymer etch resist can be left on the structure to provide for further electrical insulation. Then, the current collector metal is deposited over the electrical insulating polymer etch resist, such that the remaining polymer etch resist becomes part of the dielectric structure.

In a further approach, the window through the dielectric layer is formed by ablating the dielectric layer with a laser. A pulsed laser can be used which is scanned across the surface to ablate a regular pattern of holes or other selected pattern through the dielectric as the windows. The windows are generally positioned to correspond with doped domains along the silicon. In some embodiments, an infrared laser can be used to ablate the dielectric layer to expose the underlying silicon material without significantly damaging the silicon layer. The metal current collectors can be patterned over the windowed dielectric layer with the metal of the current collector contacting the silicon layer generally at a doped domain.

In an alternative approach, metal current collectors are patterned over the dielectric as described further below. In this approach the current collectors are placed over a dielectric layer without windows. Good connections between the current collectors and the doped contacts can be formed through the laser firing of an intense pulse to melt the metal that drives through the dielectric, as described generally in U.S. Pat. No. 6,982,218 noted above. The laser firing forms a very good connection between the metal current collector and the doped contacts through a hole formed through the dielectric for the effective harvesting of the photocurrent with good efficiency. The positioning and number of the connection points between the current collectors and the doped contacts through holes formed in the dielectric can be selected to achieve desired performance. Additionally or alternatively, an anneal step, such as a laser anneal, can be performed following the contact of metal current collector material with doped contacts of the semiconductor to improve the current collector-semiconductor interface.

Current collectors can be formed also using either of two efficient laser processing approaches. In particular, for one approach metal current collectors for the opposite poles of the cell can be performed based on selective etching following patterning to form an alloy between two metal layers. Generally, prior to the patterning two or more metal layers are formed over the surface or a portion thereof. The laser is scanned over the surface in a desired pattern to identify the locations for metal removal or in some embodiments for retaining the metal. Following the patterning, the surface of the metal has locations with the original top metal exposed and other locations with an alloy along the top surface. A wet or dry etch can be performed to selectively remove either the alloy or the original metal along with remaining portions of the lower metal at the etched locations to form a trench through the metal. In some embodiments, the lower metal comprises aluminum or an aluminum alloy, and the upper metal is nickel or a nickel alloy, such as a nickel vanadium alloy. The resulting aluminum nickel alloy is a eutectic alloy with a low melting point that can be effectively removed selectively to leave the original nickel (nickel vanadium alloy) essentially un-etched. This alloy-based laser patterning approach consumes less power than approaches based on ablating a metal for patterning, and the ability to use a lower laser power reduces the incidence of damage to the underlying structure. Other focused energy sources can be used in place of the laser with similar advantages. This alloy-based selective patterning approach is described further in copending U.S. patent application Ser. No. 12/469,101 filed on the same date as the present application to Srinivasan et al., entitled “Metal Patterning for Electrically Conductive Structures Based on Alloy Formation,” incorporated herein by reference.

In alternative embodiments, a polymer etch resist is placed over the metal layers. The polymer etch resist is then ablated with a pulsed laser scanned over the surface at selected locations where it is desired for metal to be removed. Then, an etching step is performed to etch the metal down to a dielectric layer under the metal. The polymer etch resist can then be removed. This soft ablation approach can be similar to the soft ablation summarized above with respect to selective etching of the dielectric layer.

The solar cells described herein can incorporate one or more desirable features described herein. The improved processing approaches described herein enable the formation of the desirable cell features. The processing approaches are also generally efficient, and the processes are generally useful for the processing of large area semiconductor sheets, such as silicon foils. Thus, efficient and commercially suitable processing approaches are described that can be effectively used for the formation of cost effective solar cells with excellent performance characteristics.

### Solar Cell Structures

Back contact solar cells have patterns of p-doped and n-doped domains or contacts across the back side of the cell. The patterns and properties of the doped contacts are designed to achieve high cell efficiency while being consistent with cost effective processing approaches described further below. The back side structure has a stack of elements that provide for the harvesting of current from the doped contacts with current collectors. A dielectric layer can be located on top of the semiconductor layer, and portions of metal associated with a current collector extend through the dielectric layer to touch an appropriate doped contact. The structures of the current harvesting elements are also suitable for placement along thin silicon foils.

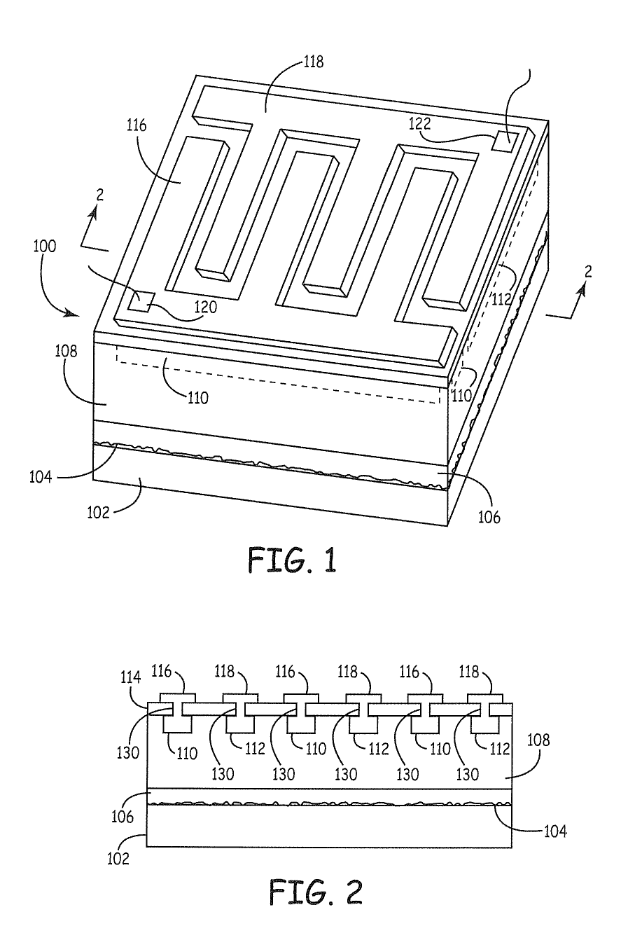

Referring to FIG. 1, an embodiment of a back contact silicon-based solar cell is shown schematically. Solar cell 100 is shown in a sectional view in FIG. 2. Solar cell 100 comprises front transparent layer 102, polymer/adhesive layer 104, front passivation layer 106, semiconducting layer 108, p-doped domains 110, n-doped domains 112, back passivation layer 114, current collectors 116, 118 and external circuit connections 120, 122.

Front transparent layer 102 provides for light access to semiconducting layer 108. Front transparent layer 102 provides some structural support for the overall structure as well as providing protection of the semiconductor material from environmental assaults. Thus, in use, the front layer 102 is placed to receive light, generally sun light, to operate the solar cell. In general, front transparent layer can be formed from inorganic glasses, such as silica-based glasses, or polymers, such as polycarbonates, composites thereof or the like. The transparent front sheet can have an antireflective coating and/or other optical coating on one or both surfaces. Suitable polymers, e.g., adhesives, for polymer/adhesive layer 104 include, for example, silicone adhesives or EVA adhesives (ethylene vinyl acetate polymers/copolymers). In general, the polymer/adhesive is applied in a thin film sufficient to provide the desired adherence between the front transparent layer 102 and under-layer 106 or semiconductor layer 108 if under-layer 106 is not present.

Front passivation layer 106, if present, generally comprises a dielectric layer. Similarly, back passivation layer 114 generally also comprises a dielectric material. Suitable inorganic materials to form passivation layers include, for example, stoichiometric and non-stoichiometric silicon oxides, silicon nitrides, and silicon oxynitrides, silicon carbides, silicon carbonitrides, combinations thereof or mixtures thereof, with or without hydrogen additions or other transparent dielectric materials. In some embodiments, passivation layers can comprise, for example, SiNₓO_{y}, x≦4/3 and y≦2, silicon oxide (SiO₂), silicon nitride (Si₃N₄), silicon rich oxide (SiOₓ, x<2), or silicon rich nitride (SiNₓ, x<4/3). In addition to inorganic materials, the passivation layer or a portion thereof can comprise an organic polymer, such as polycarbonates, vinyl polymers, fluorinated polymers, such as polytetrafluoroethylene, polyamides and the like. The polymer can provide desirable electrical insulation properties. The polymer material can be selected appropriately for the corresponding process for the formation of the windows using a selected process as described further below. In some embodiments, the passivation layer can comprise an inner inorganic layer adjacent the silicon material and an organic layer over the inorganic layer. The organic layer can comprise a polymer etch resist.

The passivation layers generally can have a thickness generally from about 10 nanometers (nm) to 800 nm and in further embodiments from 30 nm to 600 nm and in further embodiments from 50 nm to 500 nm. A person of ordinary skill in the art will recognize that additional ranges of thicknesses within the explicit ranges above are contemplated and are within the present disclosure. The passivation layers can protect the semiconductor material from environmental degradation, reduce surface recombination of holes and electrons, and/or provide structural design features, as well as provide anti-reflecting properties for front surfaces. The passivation layer generally is also chemically inert so that the cell is more resistant to any environmental contaminants.

The front passivation layer and/or rear passivation layer generally can have texture to scatter light into the semiconductor layer, for example, to increase effective light path and corresponding absorption of the light. In some embodiments, the textured material can comprise a rough surface with an average peak to peak distance from about 50 nm to about 100 microns. The texture can be introduced during the deposition process to form the passivation layer and/or the texture can be added subsequent to the deposition step.

Semiconductor layer 108 can comprise silicon, such as crystalline silicon. In general, it is desirable to use relatively thin sheets of silicon, and the sheets can be single crystalline or polycrystalline. For example, modest surface area sheets can be cut from single crystal silicon ingots. Also, polycrystalline silicon ribbons can be formed in a chemical vapor deposition type process by growing the silicon from a gaseous feedstock onto an initial powder of silicon. An example of such a process is described in published PCT application WO 2009/028974A to Vallera et al., entitled “Method for the Production of Semiconductor Ribbons from a Gaseous Feedstock,” incorporated herein by reference.

In some embodiments, individual solar cells can be formed from modest sized sheets having intermediate thicknesses. For example, in some embodiments semiconductor layer 108 can have a surface area from about 50 cm² to about 2000 cm², and in further embodiments from about 100 cm² to about 1500 cm². These sheets can have average thicknesses from about 50 microns to about 1000 microns and in further embodiments from about 100 microns to about 500 microns. These moderate area sheets can be single crystalline. However, in some embodiments, semiconductor layer 108 is a thin, large area sheet of polycrystalline silicon.

Recently technology has been developed for the formation of large area, thin polycrystalline silicon foils. The thin nature of the foils provides for the reduced use of silicon material, and the potential for large area structures can be particularly useful for corresponding large format products, such as optical displays and solar cells. If the foil has an appropriate surface area, an entire module can be processed from a single silicon foil sheet. In some embodiments, the foils can have a thickness no more than about 300 microns, in further embodiments no more than about 200 microns, in additional embodiments from about 3 microns to about 150 microns, in other embodiments from about 5 microns to about 100 microns and in some embodiments from about 8 microns to about 80 microns. A person of ordinary skill in the art will recognize that additional ranges of thicknesses within these explicit ranges are contemplated and are within the present disclosure.

In order to reduce the use of silicon in solar cells, thin polycrystalline silicon foils can be desirable to achieve a high efficiency with a modest consumption of materials. In some embodiments, the inorganic foils, e.g., silicon sheets, can have a large area as well as being thin. For example, the foils can have a surface area of at least about 900 square centimeters, in further embodiments at least about 1000 cm², in additional embodiments from about 1500 cm² to about 10 square meters (m²) and in other embodiments from about 2500 cm² to about 5 m². A person of ordinary skill in the art will recognize that additional ranges of surface area within the explicit ranges above are contemplated and are within the present disclosure. For silicon foils and perhaps other polycrystalline inorganic materials, the electronic properties can be improved in some embodiments through the recrystallization of the silicon following the initial formation of the thin silicon layer. A zone melt recrystallization process can be applied to improve the electrical properties, such as carrier lifetimes, of the silicon material.

Elemental silicon or germanium foils, with or without dopants, can be formed through reactive deposition onto a release layer. It may be desirable to have light doping of the layer to increase electron mobilities. In general, the silicon can have an average dopant concentration of about 1.0×10¹⁴ to about 1.0×10¹⁶ atoms per cubic centimeter (cc) of boron, phosphorous or other similar dopant. A person or ordinary skill in the art will recognize that additional ranges of light dopant levels within the explicit ranges above are contemplated and are within the present disclosure.

The foil can be separated from the release layer for incorporation into a desired device. In particular, scanning reactive deposition approaches have been developed for deposition onto an inorganic release layer. The foils can be deposited, for example, using light reactive deposition (LRD™) or with chemical vapor deposition (CVD), e.g., sub-atmospheric pressure CVD or atmospheric pressure CVD. Reactive deposition approaches can effectively deposit inorganic materials at a significant rate. LRD™ involves the generation of a reactant flow from a nozzle directed through an intense light beam, such as a laser beam, which drives the reaction to form a product composition that is deposited onto a substrate that intersects the flow. The light beam is directed to avoid striking the substrate, and the substrate is generally moved relative the flow to scan the coating deposition across the substrate and an appropriately shaped nozzle oriented appropriately relative to the light beam can scan the coating composition to coat an entire substrate in a single linear pass of the substrate past the nozzle. LRD™ reactive deposition onto a release layer is described generally in U.S. Pat. No. 6,788,866 to Bryan, entitled “Layer Material and Planar Optical Devices,” incorporated herein by reference as well as in published U.S. patent application 2007/0212510A to Hieslmair et al., entitled “Thin Silicon or Germanium Sheets and Photovoltaics Formed From Thin Sheets,” incorporated herein by reference.

CVD is a general term to describe the decomposition or other reaction of a precursor gas, e.g., silanes, at the surface of a substrate. CVD can also be enhanced with plasma or other energy source. CVD deposition can be well controlled to yield a uniform thin film at a relatively rapid deposition rate when performed in scanning mode. In particular, a directed reactant flow CVD has been developed with scanning of the deposition across a substrate surface in an enclosure at a pressure lower than the ambient pressure. The reactant is directed from a nozzle to the substrate, which is then moved relative to the nozzle to scan the coating deposition across the substrate. Atmospheric pressure CVD can also be used to deposit appropriately thick layers at reasonable rates. Furthermore, techniques have been developed to perform scanning, directed flow CVD onto selected substrates at below atmospheric pressure, such as form about 50 Torr to about 700 Torr and below ambient pressures. For silicon films, CVD can be performed on a substrate at atmospheric pressure or below atmospheric pressure at high temperatures ranging from 600° C. to 1200° C. The substrate holder generally is appropriately designed for use at high temperatures. CVD deposition onto a porous release layer is described further in published U.S. patent application 2009/0017292 to Hieslmair et al., entitled “Reactive Flow Deposition and Synthesis of Inorganic Foils,” incorporated herein by reference.

While the use of a large area, thin semiconductor sheet can be advantageous for forming a plurality of solar cells, in some embodiments smaller sections of thin semiconductor sheets can be placed along a transparent substrate with appropriate alignment. Thus, each section of a semiconductor sheet can be a desired size for an individual solar cell or one ore more sections can also be cut to form smaller sections of semiconductor sheets for individual cells. However, the smaller sheets of semiconductor can be obtained from a desired source, such as being cut from an ingot or the like. Whether cut form a large area foil or assembled from individual thin sheets of semiconductor or some combination thereof, an array of solar cells can be simultaneously processed on a transparent substrate to form the back contact structure using the processes described herein.

In general, p-dope contacts 110 and n-doped contacts 112 can be islands over semiconductor layer 108 or domains embedded within the top surface of semiconductor layer 108. The formation of doped silicon islands as doped contacts over a silicon semiconductor layer is described further in published U.S. patent application 2008/0160265 to Hieslmair et al., entitled “Silicon/Germanium Particle Inks, Doped Particles, Printing and Processes for Semiconductor Application,” incorporated herein by reference. As shown in FIGS. 1 and 2, doped contacts 110, 112 are embedded within semiconductor layer 108. Embedded doped domains are generally formed through the drive in of atoms of a dopant element into the silicon which can be heated, for example, to melting, to provide for the dopant drive in. In particular, As, Sb and/or P dopants can be introduced into the silicon particles to form n-type semiconducting materials in which the dopant provide excess electrons to populate the conduction bands, and B, Al, Ga and/or In can be introduced to form p-type semiconducting materials in which the dopants supply holes. Generally, the average dopant levels can be from about 1.0×10¹⁸ to about 5×10²⁰, in further embodiments 2.5×10¹⁸ to about 1.0×10²⁰ and in other embodiments form 5.0×10¹⁸ to about 5.0×10¹⁹ atoms per cubic centimeter (cc). A person of ordinary skill in the art will recognize that additional ranges of dopant levels within these explicit ranges are contemplated and are within the present disclosure. Processes for the formation of isolated, relatively deep dopant contacts are described further below.

Doped contacts 110, 112 are patterned along the top surface of semiconductor layer 108. There can be one or a plurality of doped contacts of each dopant type, i.e., p-doped and n-doped. For example, a checkerboard alternating pattern of p-doped contacts and n-doped contacts and variations thereof are presented as an example in published U.S. patent application 2008/0202576 to Hieslmair, entitled “Solar Cell Structures, Photovoltaic Panels and Corresponding Processes,” incorporated herein by reference. This published application also describes point contacts arranged in rows with like doped domains.

In some embodiments, the domains of doped contacts with different dopants can adjoin each other at edges. However, it has been found that good cell performance can be achieved with spaced apart doped contacts with different dopants. The coverage of the semiconductor surface with doped domains can involve a balance of factors, such as current harvesting efficiency and back recombination. Thus, having spaced apart doped contacts can be expected to reduce back recombination. Also, it has been found with appropriately spaced apart doped contacts, that the doped contacts can be formed relatively deeply into the semiconductor material while improving the performance of the solar cell, which implies more efficient harvesting of the photocurrent.

Also, doped contacts can be formed as rough stripes within the substrate surface. Adjacent stripes with the opposite dopant electrical properties can be spaced apart such that alternating stripes are formed. In general, individual stripes can have aspect ratios of a length to a width of at least about a factor of ten, in further embodiments at least a factor of 15 and in additional embodiments at least a factor of 25. In general, the width can range form about 5 microns to about 700 microns, in further embodiments from about 10 microns to about 600 microns and in other embodiments from about 15 microns to about 500 microns. The length can be long based on the size of the semiconductor structure and can be on the order of centimeters and even meters, although the lengths of stripes can be broken up and/or turned along the surface to cover shorter lengths. In general, the stripes may not have straight edges, and the dimensions can be estimated based on averaging over fluctuations of varying edge distances. A person of ordinary skill in the art will recognize that additional ranges of doped contact dimensions within the explicit ranges above are contemplated and are within the present disclosure.

As noted above, the edge-to-edge spacing between the adjacent doped contacts with opposite dopant polarity can influence cell performance. In some embodiments, the edge-to-edge spacing between adjacent striped domains corresponding to doped contacts can be from about 5 microns to about 500 microns, in further embodiments, from about 10 microns to about 400 microns and in additional embodiments from about 20 microns to about 350 microns. Again, variations in the edges of the doped contacts can be approximately averaged over to evaluate the average pitch. A person of ordinary skill in the art will recognize that additional ranges of average pitch within the explicit ranges above are contemplated and are within the present disclosure. The stripes of doped contacts can be a portion of a more complex pattern that may or may not interconnect regions of stripes. For example, an interdigitated pattern similar to the schematic current collector pattern of FIG. 1 can be used. In some embodiments, more complicated patterns have sections with adjacent stripes of alternating dopant types, which contribute to desirable cell performance. These striped patterns can also be formed efficiently using the processing approaches described below.

As noted above, it has been found that for spaced apart dopant contacts, effective cell performance can be achieved using relatively deep contacts. In particular, the doped contacts can have an average depth from about 100 nm to about 5 microns, in farther embodiments from about 150 nm to about 4 microns and in additional embodiments from about 200 nm to about 3 microns. A person of ordinary skill in the art will recognize that additional ranges of dopant depth within the explicit ranges above are contemplated and are within the present disclosure. The depth based on the added dopant profile, i.e. relative to the bulk dopant concentration, can be fixed at the depth at which no more than about 5 atomic percent of the added dopant is below the depth in the semiconductor layer. The dopant profile can be measured using Secondary Ion Mass Spectrometry (SIMS) to evaluate the elemental composition along with sputtering or other etching to sample different depths from the surface.

In some embodiments, the dopant profile can be designed to introduce desirable non-uniformity. For example, the dopant can be selected to have a higher dopant concentration near the surface. As described below, this can be accomplished, for example, with two dopant drive in steps for the same dopant type at roughly equivalent locations. Of course, based on the nature of the dopant drive in process, the dopant is not completely uniform as an initial matter. With an engineered dopant profile, the top 10% of the thickness of the contact can have an average dopant concentration that is at least a factor of 4, in some embodiments from a factor of 4.5 to a factor of 20 and in additional embodiments from a factor of 5 to a factor of 15 greater than the average dopant concentration for the contact at the position 20-30% of the contact depth from the top of the contact. As an example, if the contact has a depth of 1 micron, the average dopant concentration in the top 100 nanometers is compared with the average dopant concentration in the layer between 200 and 300 nm below the top surface. A person of ordinary skill in the art will recognize that additional ranges of dopant increase within the explicit ranges above are contemplated and are within the present disclosure.

Additionally or alternatively, the dopant concentration can also be designed to vary laterally across the surface of the contact to adjust the current collection. For example, the center of a stripe of doped contact can have a dopant profile with a higher dopant concentration, optionally also with a shallower profile, along one section of the stripe. In particular, it can be desirable to have a higher dopant level in a profile, such as a shallower profile, along the interior of the stripe, such as along the center of the stripe. Of course, edge effects occur naturally in the processing that are substantially different from the design dopant domains. If desired to avoid edge effects, along a stripe section of a doped domain, the five percent of the width along each edge can be excluded from consideration. In some embodiments, the laterally engineered doped domains can have a shallow doped region covering no more than about 50% of the remaining (optionally edge excluded) area of the contact, and in further embodiments no more than about 40% of the remaining area with an average depth that is no more than about half of the average depth and in other embodiments no more than about 35% of the average depth of the dopant in the doped contact away from the shallow doped region. In some embodiments, the shallow doped region also has a surface dopant concentration that is at least about a factor of five and in some embodiments at least a factor of 7.5 times greater than the average dopant concentration of the doped region. A person of ordinary skill in the art will recognize that additional ranges of areas, dopant depths and dopant concentrations within the explicit ranges above are contemplated and are within the present disclosure.

The feature of additional dopant along the surface can be combined with the lateral variation in the dopant concentration. For example, the center section of the stripe can have a higher or enhanced dopant concentration while other portions of the stripe do not have the enhanced dopant levels near the surface. Additional combinations of the described engineered non-uniformity can be used based on the examples provided.

The general properties of back passivation layer 114 are similar to the properties of the front passivation layer described above. Referring to FIG. 2, back passivation layer 114 however has holes or windows 130 that provide for electrical contact between current collectors 116, 118 and doped contacts 110, 112, respectively. Two desirable approaches for forming the holes or windows are described below. At the locations of windows or holes 130, the material, e.g., metal, of the current collectors penetrates through passivation layer 114 to contact the respective doped domain. Generally, windows 130 cover significantly less area along the surface than corresponding doped domains. In particular, it is found that sufficient electrical connection between the current collector is obtained to achieve good cell performance with contact between the elements over a fraction of the doped domain surface. Specifically, windows 130 can cover an area of the surface from about 2 percent to about 80 percent of the doped contact area, in further embodiments from about 3 to about 70 percent and in other embodiments from about 5 to about 60 percent of the doped contact area. A person of ordinary skill in the art will recognize that additional ranges of window areas within the explicit ranges

As noted above, the doped domains along the semiconductor surface can have different dopant profiles at different locations of the doped contact along the surface. In some embodiments, some portions of a doped contact can have an enhanced dopant concentration along the surface relative to other portions of the doped contact. In these embodiments, it can be desirable for the windows to be positioned along at least a portion of the surface with higher dopant concentration to increase current flow and in some embodiments, the windows can be aligned such that at least about 75 percent of the exposed area has enhanced surface dopant, in further embodiments at least about 90 percent and in other embodiments at least about 95 percent of the exposed area has enhanced surface dopant relative to the average surface dopant concentration of the doped contact. A person of ordinary skill in the art will recognize that additional ranges of surface exposure within the explicit ranges above are contemplated and are within the present disclosure.

Current collectors 116, 118 are placed along the surface of back passivation layer 114 over passivation layer 114 and doped contacts 110, 112. Current collectors 116, 118 form opposite electrical poles of the cell. The current collectors make contact with appropriate doped contacts through windows 130. In other words, portions of current collector material extend through windows 130 to make contact with the doped contact below the window. Thus, the pattern of the current collectors generally is based on the positions of the doped contacts as well as the windows providing access to the doped contacts. In some embodiments, current collectors 116, 118 comprise electrically conductive elemental metal or a plurality thereof. Suitable metals include, for example, aluminum, copper, nickel, zinc, alloys thereof or combinations thereof. In some processing approaches, it is desirable to have a plurality of metal layers within the current collectors.

In some embodiments, the average total metal thickness can be from about 25 nanometers (nm) to about 30 microns, in further embodiments from about 50 nm to about 15 microns, in other embodiments from about 60 nm to about 10 microns and in additional embodiments from about 75 nm to about 5 micron. In general, the current collectors cover a greater surface area than the windows. Specifically, the combined area of the current collectors can be at least about 20 percent greater than the area of the windows, in further embodiments at least about 40 percent greater and in additional embodiments at least about 60 percent greater than the area of the windows. A person of ordinary skill in the art will recognize that additional ranges of average thickness and area coverage within the explicit ranges above are contemplated and are within the present disclosure.

The metal can further contribute to the solar cell performance through the reflection of light back through the cell. Therefore, there can be advantages in having greater coverage of the back surface of the cell with metal of the current collectors. However, the opposite poles of the cell are effectively electrically isolated to prevent short circuiting of the cell. Thus, trenches or the like are located between the current collectors of opposite polarity. The trenches generally extend down to the passivation layer, although trivial amounts of metal within the trenches that do not provide significant electrical shunts are insignificant. In some embodiments, the trenches between adjacent sections of the current collectors of opposite polarity have an average distance of at least about 5 microns and in further embodiments from about 10 microns to about 500 microns. A person of ordinary skill in the art will recognize that additional ranges of trench widths within the explicit ranges above are contemplated and are within the present application.

External connections 120, 122 can be soldered or welded to current collectors 116, 118, respectively. The external connections can provide wired connections in some embodiments. In other embodiments, external connections 120, 122 can comprise patterned metal that extends, such as over an insulating material bridge, to adjacent solar cells or contacts with external circuits. Other structures for external connections 120, 122 can be used as appropriate.

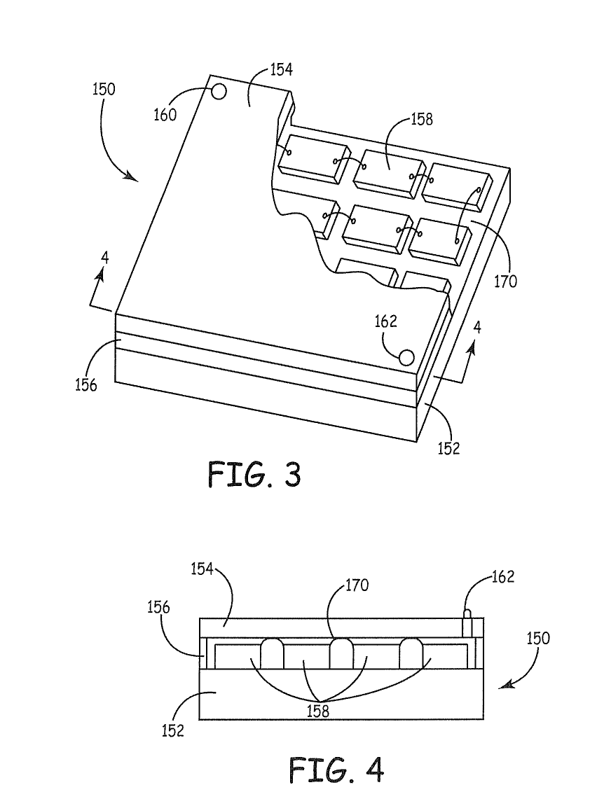

A schematic view of a photovoltaic module is shown in FIG. 3. Photovoltaic module 150 can comprise a transparent front sheet 152, a protective backing layer 154, a protective seal 156, a plurality of photovoltaic cells 158 and terminals 160, 162. A sectional view is shown in FIG. 4. Transparent front sheet 152 can be a sheet of silica glass or other suitable material that is transparent to appropriate sun light wavelengths and provides a reasonable barrier to environmental assaults such as moisture. Backing layer 154 can be any suitable material that provides protection and reasonable handling of the module at an appropriate cost. Backing layer 154 does not need to be transparent and in some embodiments can be reflective to reflect the light that transmitted through the semiconductor back through the semiconductor layer where a portion of the reflected light can be adsorbed. Protective seal 156 can form a seal between front protective sheet 152 and protective backing layer 154. In some embodiments, a single material, such as a heat sealable polymer film, can be used to form backing layer 154 and seal 156 as a unitary structure.

Solar cells 158 are placed with their front surface against transparent front sheet 152 so that solar light can reach the semiconductor material of the photovoltaic cells. Solar cells can be connected electrically in series using current collectors 170, conductive wires or the like. End cells in the series can be connected respectively to terminals 160, 162 that provide for connection of the module to an external circuit.

Suitable polymeric backing layers include, for example, Tedlar® “S” type, a polyvinyl fluoride film, from DuPont. With respect to reflective materials, the polymer sheet for the backing layer can be coated with a thin metal film, such as metalized Mylar® polyester film. A protective seal joining the transparent front sheet and a backing layer can be formed from an adhesive, a natural or synthetic rubber or other polymer or the like.

### Processes for Forming Solar Cell Components

Improved processing approaches provide for formation of the current harvesting component of the solar cell. These can be effectively applied for the formation of back contact solar cells, although the processing steps can also be useful for other solar cell designs. Specifically, a laser driven dopant drive in can form effective doped contacts along a specified design, which can effectively comprises approximate stripes along the surface of the semiconductor. Laser patterning can also be used to select points of windows through the passivation layer for electrical connection between the current collector and the doped contacts. Also, an energy beam, such as a laser beam can also be used for patterning the current collectors to provide for electrically isolated current collectors for the two poles of the cell. Used alone or in combination, these processing approaches provide effective approaches for forming cells with excellent performance at a reasonable cost.

In general, the improved processing approaches can be combined for the formation of doped contacts, conduction pathways through a passivation layer and current collectors. As described further below, each of the improved processes involve a scanning laser system, which may provide for simplified designs of a processing line for the formation of the solar cells based on these processing steps. In some embodiments, it may be desirable to share common equipment for these processing steps, if desired. However, the improved processing steps described herein can be used individually or in subcombinations, such as in combination with other alternative processing steps, such as conventional processing steps. For example, the method of forming the doped contacts herein can be used with conventional processing steps to provide connections with a current collector through a passivation layer. As another example, if a conventional approach is used is used to form doped contacts, the improved approaches herein can be used for the formation of windows to connect the doped contacts with a current collector.

The laser patterning process can be performed for the formation of the doped domains with structures as described above. The driving of the dopant into the semiconductor material involves the formation of a layer comprising one or more dopant sources over the semiconductor material. A laser with a wavelength from the green to infrared laser is then used to drive the dopant deep into the semiconductor to form a relatively deep dopant contact at the selected locations. In particular, an infrared laser can be advantageously used, as described in the examples below. As noted above, desirable cell performance has been obtained from the formation of segments of doped domains with a stripe configuration. The laser can efficiently perform dopant drive in consistent with forming doped contact with a stripe configuration.

In the improved dopant contact formation approaches described herein, a dopant source can be deposited over the semiconductor surface or over a portion of the surface, and in some embodiments, two or more dopant sources can be patterned over the surface, for example, through a printing process. For embodiments in which different dopant sources are used sequentially, the formation of the doped contact can comprise the following steps: 1) Deposit a layer of a first dopant source; 2) Scan laser beam across the semiconductor surface to form selected doped contacts with a first dopant; 3) Remove the first dopant source; 4) Deposit a layer of a second dopant source; 5) Scan laser beam across the semiconductor surface to form selected doped contacts with a second dopant; and 6) Remove the second dopant source. These steps can be repeated if desired with the same or different parameters to alter the dopant profiles, for example, to increase the amount of dopant in shallow regions of the doped contacts. The resulting patterned semiconductor material is then ready for further processing to complete the back surface of the cell for current harvesting.

In alternative or additional embodiments, the dopant sources can be patterned along the surface such that both sources for both n-dopants and p-dopants are simultaneously present along the surface. Then, a single laser processing step can be used to form both n-doped contacts and p-doped contacts. The semiconductor surface can be cleaned and/or etched to remove the dopant sources after the laser processing step. Since n-dopants and p-dopants can be driven into the semiconductor in a single laser step, the number of processing steps can be reduced, less dopant source is wasted and processing time can be reduced. Patterning of dopant sources can be performed, for example, with printing approaches, such as screen printing or inkjet printing.

The dopant sources generally are compositions comprising the desired dopant elements. For example, phosphorous or boron containing liquids can be deposited. In particular, suitable inks can comprise, for example, trioctyl phosphate, phosphoric acid in ethylene glycol and/or propylene glycol or boric acid in ethylene glycol and/or propylene glycol. In other embodiments, doped silica particles can be used. The formation of good dispersions of doped silica nano-particles that can be deposited as a thin relatively uniform layer are described further in published U.S. patent application 2008/0160733A to Hieslmair et al., entitled “Silicon/Geranium Oxide Particle Inks, Inkjet Printing and Process for Doping Semiconductor Substrates,” incorporated herein by reference. The solvents or a portion thereof can be removed prior to performing the dopant drive in.

A particularly convenient and cost effective dopant source comprises spin-on glasses. Spin-on glasses are silicon-based compositions that react to form silica glass, generally through a decomposition reaction upon heating in an oxidizing atmosphere. Various doped spin-on glass compositions are commercially available. For example, doped spin-on-glasses are available from Desert Silicon (AZ, USA). Spin-on-glass compositions can comprise polysiloxane polymers in a suitable organic solvent, such as an alcohol. Specific formulations are described in U.S. Pat. No. 5,302,198 to Alman, entitled “Coating Solution for Forming Glassy Layers,” incorporated herein by reference. This patent describes the introduction of boron or phosphorous dopants at levels of about 5 to 30 weight percent. Alternative compositions are described in U.S. Pat. No. 7,270,886 to Lee et al., entitled “Spin-On Glass Compositions and Method of Forming Silicon Oxide Layer Semiconductor Manufacturing Process Using the Same,” incorporated herein by reference.

Spin coating can be a suitable approach for applying the dopant source over the semiconductor surface. For example, the substrate can be spun at speeds on the order of 1000 revolutions per minute to obtain a uniform coating. The viscosity can be adjusted to obtain the desired coating properties at an appropriate spin speed. However, other coating approaches can be used, and these coating approaches may be particularly desirable for larger area substrates or more fragile substrates. Alternative coating approaches include, for example, spray coating, knife edge coating, extrusion, or the like. These alternative coating approaches can be effectively used to form layers of sufficient uniformity. In general, the coating thickness can be less than about a micron. An appropriate coating thickness can be selected for a particular dopant source based on a target dopant level with straightforward empirical adjustment based on the teachings herein. Printing approaches can be used for the patterning of two or more dopant sources along a semiconductor surface. Inkjet resolution over large areas is presently readily available at 200 to 800 dpi. Also, inkjet resolution is continuing to improve. Two inks generally are used, with one ink providing n-type dopants, such as phosphorous and/or arsenic, and the second ink providing p-type dopants, such as boron, aluminum and/or gallium. The viscosity of the dopant source can be adjusted for the printing process.

To obtain a desired depth of dopant drive in, a laser is used with a wavelength in the red to infrared wavelengths can be used. The wavelength generally is selected to penetrate sufficiently deeply into the silicon material to drive the dopant down to a desired depth. In some embodiments, the laser generally has a wavelength from about 600 nm to about 5 microns, and in further embodiments from 650 nm to 4 microns. In some embodiments it is desirable to use wavelengths in the near infrared from about 750 nm to about 2500 nm. In particular, an SPI™ 20 watt fiber laser has a wavelength of 1064 nm. A person of ordinary skill in the art will recognize that additional ranges of laser frequency within the explicit ranges above are contemplated and are within the present disclosure.

In general, a significant parameter is the light pulse energy density with respect to supplying sufficient energy for dopant drive in, which involves heating the silicon below the dopant source. The pulse energy density can be matched roughly to provide the desired heating for the desired thickness of silicon based on the absorption properties of the silicon at the particular wavelength. In general, reasonable pulse energy densities can be from about 0.25 to about 25 Joules per square centimeter (J/cm²), in further embodiments from about 0.5 to about 20 J/cm² and in other embodiments from about 1.0 to about 12 J/cm². A person of ordinary skill in the art will recognize that additional ranges of pulse energy densities within the explicit ranges above are contemplated and are within the present disclosure.

In general, it is desirable to scan the laser across the surface to form a selected pattern for dopant drive in. With a pulsed laser and a linear scan, desired stripes can be formed for the shape of the doped contacts. The laser beam, though, can also be scanned around curves and turns, and can also be turned off leave desired gaps based on a target doping pattern.

In general, the line width can be adjusted using the optics to select the corresponding light spot size at least within reasonable values. The line widths of the doped domain correspond to the spot size. In some embodiments, it may be desirable to form a single stripe of domed domain using a plurality of adjacent or overlapping sections where each section is formed from a laser scan such that a stripe may involve a corresponding plurality of laser scans with an appropriate lateral displacement to form the adjacent or overlapping sections. Thus, a single stripe of a doped domain can be formed from 2, 3, 4, 5 or more sections. The dopant profiles in the sections may or may not be approximately equivalent. As noted above, it can be desirable to include a shallow section of a doped domain with a shallower dopant profile and/or a higher dopant concentration. Thus, for example, if the stripe is formed from three sections, the middle section can be processed to have a shallower dopant profile and/or with a higher dopant concentration. The scanning of the laser can be adjusted to provide the different dopant profiles for the different sections. Additionally or alternatively, the sections can be performed with a different dopant sources that are sequentially deposited, generally with cleaning between the steps. Corners and/or turns of doped domains can similarly involve adjacent and/or overlapping sections that can join up to sections of stripes.

The light intensity is generally not uniform across the light beam, but the beam shape can be adjusted to be Gaussian or flat-top type depending on the optics arrangement. Pulse frequencies in some embodiments can be from about 5 kilohertz (kHz) to about 5000 kHz, in further embodiments from about 10 kHz to about 2000 kHz, and in additional embodiments from about 25 kHz to about 1000 kHz. Scanning speeds can range in some embodiment from about 0.05 to about 15 meters per second (m/s), and in further embodiments from about 0.15 to about 12 m/s, and in other embodiments from about 0.5 to about 10 m/s. For dopant processing with the laser, a wider laser pulse profile generally results in a deeper dopant profile. Thus, it can be desirable to have a laser pulse that has a duration of at least about 50 nanoseconds (ns), and in some embodiments at least about 70 ns. A person of ordinary skill in the art will recognize that additional ranges of pulse frequencies, scanning speeds and pulse duration within the explicit ranges above are contemplated and are within the present disclosure.

Based on a particular spot size, the scan speed of the light beam across the substrate can be correlated with pulse frequency so that adjacent pulses may overlap to a selected degree to provide a contiguous processed domain with dopant drive in. In some embodiments, adjacent spots can be spaced to not overlap if multiple passes of the laser over the pattern provide eventual overlap to form a contiguous doped contact. Whether or not adjacent pulses of a single scan overlap, it has been found that in some embodiments it is desirable to use a lower pulse energy density and scan over the line or other patterned shape a plurality of times. A multiple pass approach can result in less damage to the substrate and a more even line. In some embodiments, it may be desirable to provide two passes, three passes, four passes, five passes or more than five passes of the light beam over the same pattern of the surface to obtain more desirable results. Multiple passes at lower power can result in a smoother surface after completion of the doping.

Since the intersection of the light beam with the substrate is generally roughly circular, some overlap can be desirable to get a continuous doped contact along the line of laser pulses, although multiple passes over the same region can smooth out gaps from adjacent pulses. For convenience, we define a light spot as a circle along the surface with 95 percent of the light power included within the perimeter. The light pulse rate and scanning speeds can be selected such that the centers of the image of adjacent light pulses are displaced from each other in the range from 0.1 to about 1.5 times the light image diameter, in further embodiments from about 0.2 to about 1.25 times the light image diameter and in additional embodiments from about 0.25 to about 1.1 times the light image diameters. A person of ordinary skill in the art will recognize that additional ranges within the explicit ranges above are contemplated and are within the present disclosure.

The light beams can be scanned across the substrate surface using commercial scanning systems or similarly designed custom systems. Generally, these systems comprise optical elements to scan a laser beam to a selected location. Position detectors useful in optical scanning systems are described further in U.S. Pat. No. 6,921,893 to Petschik et al., entitled “Position Sensor for a Scanning Device,” incorporated herein by reference. Control systems useful for scanners are described in U.S. Pat. No. 7,414,379 to Oks, entitled “Servo Control System,” incorporated herein by reference. Commercial scanning systems or galvanometers are available form Scanlab AG (Germany) and Cambridge Technology Inc. (MA, U.S.).

A back passivation layer can be deposited by a range of selected approaches. Passivation layers can be formed from conventional techniques such as sputtering, CVD, PVD or combinations thereof techniques using, for example, commercial deposition apparatuses. In particular, passivation layers can be deposited with plasma enhanced CVD (PECVD). PECVD and/or sputtering can be desirable approaches due to the ability to perform the deposition at low temperatures. Since the passivation layers are relatively thin, these conventional approaches are reasonably efficient. In additional or alternative embodiments, Light Reactive Deposition (LRD™) can be used to deposit the passivation layer. LRD™ is described further in published PCT application WO 02/32588A to Bi et al., entitled “Coating Formation By Reactive Deposition,” and U.S. Pat. No. 7,491,431 to Chiruvolu et al., entitled “Dense Coating Formation By Reactive Deposition,” incorporated herein by reference. Furthermore, the passivation layer can be deposited using atmospheric pressure CVD or scanning sub-atmospheric CVD. Scanning Sub-Atmospheric CVD is described further in published U.S. patent application 2009/0017292 to Hieslmair et al., entitled “Reactive Flow Deposition and Synthesis of Inorganic Foils,” incorporated herein by reference. Polymer layers forming the passivation layer or a portion thereof can be deposited using polymer coating technique, such as spray coating, extrusion, knife edge coating, spin coating and the like.

Three approaches are described for the formation of connections between a current collector and a doped contact below a passivation layer. Each approach involve the use of a laser that can be directed according to a desired pattern. In a polymer ablation process, the laser is used efficiently to form a pattern through a polymer etch resist. This is then combined with an etching step that forms a window through the passivation layer. In a dielectric ablation approach, a laser is used to directly ablate windows through the dielectric layer with parameters selected to avoid significant damage to the underlying silicon semiconductor. In a laser welding process for forming connections with the doped contacts, a laser is used to drive metal from the current collector through the passivation layer to form a good junction with the doped contact below the passivation layer. The laser welding is clearly performed after the deposition of the metal for the current collector.

In the polymer ablation patterning process, a layer of polymer etch-resist is placed over the passivation layer. In general, any etch resistant polymer may be used. Convenient etch resists are commercially distributed as photoresists. In traditional processing, the photoresist is photosensitive so that light, such as UV light is patterned over the photoresist. The photoresist can be a negative photoresist where light stabilizes the photoresist against etching or a positive photoresist where light destabilizes the photoresist against etching. The polymer ablation approach is an improvement over the traditional approach in applications involving moderate resolution patterns for several reasons. First, an infrared laser can be used, and lower cost infrared lasers are commercially available. Furthermore, a single etch step is used to etch through the passivation layer, and a separate etch step is not needed to develop or etch the photoresist. Furthermore, less expensive polymers can be used that do not need to be photosensitive. Suitable negative photoresists are available, for example, from Futurrex, Inc. (NJ, USA), and strippers are sold to remove the photoresists following completion of the etching step. The etch resist polymers, e.g., photoresist, can be applied using an appropriate coating technique such as spin coating, spray coating, extrusion, knife edge coating or the like.

In the polymer ablation approach, a laser is scanned across the surface to ablate the polymer from selected locations. In general, polymers can be ablated with a relatively low power pulse. So appropriate laser pulses are directed at locations along the surface that have been selected for the placement of windows through the passivation layer. The laser pulse removes the polymer at the location of the pulse. In general, any light wavelength can be used that is absorbed by the polymer. For example, a red or infrared laser or other focused beam from a heat lamp can be effectively used for the ablation of the polymer without significantly damaging the under-layers. However, it may be desirable to reduce damage to underlayers to use a shorter wavelength light so that the light does not penetrate as deeply into the structure. For example, green, blue or ultraviolet light can be used, such as with a wavelength no more than about 550 nm, in some embodiments no more than 500 nm and in other embodiments in the near or middle ultraviolet portion of the electromagnetic spectrum with a wavelength from about 100 nm to about 400 nm. A person of ordinary skill in the art will recognize that additional ranges of light wavelength within the ranges above are contemplated and are within the present disclosure. In some embodiments, the light can be supplied with an excimer laser. In addition, an electron beam can be used to ablate the polymer. Designs of electron beam scanners developed for electron beam lithography can be adapted for this use. Appropriate systems are described, for example, in U.S. Pat. No. 6,674,086 to Kamada et al., entitled “Electron Beam Lithography System, Electron Beam Lithography Apparatus, and Method of lithography,” incorporated herein by references.

As noted above, the windows through the passivation layer cover a significantly less area of surface than the doped contacts. Thus, for patterning the windows, specific spaced apart spots can be used or line segments. In general, there is significant flexibility in designing the window pattern to achieve a desired area of the resulting windows. The pulse frequency and the scanning movement of the beam are adjusted to achieve the selected pattern, and the light beam can be turned off appropriately to form separations between sections of the windows. However, the positioning of the windows is generally selected to place the windows over areas of doped contacts. Thus, the light beam generally has a narrower focus so that the width of the window is less than the width of the doped contact following etching. In general, reasonable pulse energy densities can be from about 0.1 to about 25 Joules per square centimeter (J/cm²), in further embodiments from about 0.25 to about 20 J/cm² and in other embodiments from about 0.5 to about 12 J/cm². Scanning speeds can range in some embodiment from about 0.1 to about 10 meters per second (m/s), and in further embodiments from about 0.25 to about 9 m/s, and in other embodiments from about 1 to about 8 m/s. Pulse frequencies in some embodiments can be from about 5 kilohertz (kHz) to about 1000 kHz, in further embodiments from about 10 kHz to about 800 kHz, and in additional embodiments from about 25 kHz to about 750 kHz. A person of ordinary skill in the art will recognize that additional ranges of pulse powers, pulse frequencies and scanning speeds within the explicit ranges above are contemplated and are within the present disclosure. In general, the laser pulse conditions are selected to result in a desirable low level of damage to the doped silicon, which can absorb light that transmits through the passivation layer.

Following the formation of windows in the polymer cover, the passivation layer is etched. Suitable chemical etching can be performed, for example, with nitric/hydrofluoric acid mixtures, which do not etch the silicon. In additional or alternative embodiments, a plasma etch can be performed to remove the passivation layer through the windows in the polymer etch-resist. The selection of etchant for the passivation layer can be made consistent with the choice of polymer etch-resist. After etching the passivation layer through the windows in the polymer, windows are correspondingly formed through the passivation layer to expose regions of doped contact. Then, the polymer etch-resist may be removed, for example, by dissolving the polymer, which may or may not involve reaction or decomposition of the polymer. In some embodiments, the remaining polymer etch resist is kept to form a portion of the dielectric structure due to the electrical insulating properties of an appropriately selected polymer.

In the dielectric ablation approach, the laser is used to directly ablate the dielectric to form a window. Generally, a pulsed laser is scanned across the surface to form windows through the dielectric layer through the direct ablation of the dielectric. The selection and placement of the windows directly ablated through the dielectric layer generally can be similar to the positioning of the windows resulting from the ablation of the polymer etch, as described above. Once the windows are formed through the dielectric layer, the connection between the current collector and the doped domains of the silicon are similar regardless of the process used to form the windows.

In general, the laser parameters can be selected based on the properties of the particular dielectric layer. In particular, the laser wavelength should be reasonably absorbed by the dielectric material. The laser ablation generally can be performed to ablate the dielectric material without significantly damaging the underlying silicon material.

The laser frequency generally is selected for significant absorption by the dielectric layer. Thus, the dielectric can be ablated with reduced damage to the silicon. For silicon nitride or silicon-rich silicon nitride, the wavelength generally can be in the green or shorter, such as WV. The pulse frequency and the scanning movement of the beam are adjusted to achieve the selected pattern, and the light beam can be turned off appropriately to form separations between sections of the windows. However, the positioning of the windows is generally selected to place the windows over areas of doped contacts.

In general, reasonable pulse energy densities can be from about 0.1 to about 25 Joules per square centimeter (J/cm²), in further embodiments from about 0.25 to about 20 J/cm² and in other embodiments from about 0.5 to about 12 J/cm². Scanning speeds can range in some embodiment from about 0.1 to about 10 meters per second (m/s), and in further embodiments from about 0.25 to about 9 m/s, and in other embodiments from about 1 to about 8 m/s. Pulse frequencies in some embodiments can be from about 5 kilohertz (kHz) to about 1000 kHz, in further embodiments from about 10 kHz to about 800 kHz, and in additional embodiments from about 25 kHz to about 750 kHz. A person of ordinary skill in the art will recognize that additional ranges of pulse powers, pulse frequencies and scanning speeds within the explicit ranges above are contemplated and are within the present disclosure. In general, the laser pulse conditions are selected to result in a desirable low level of damage to the doped silicon, which can absorb light that transmits through the passivation layer.

Furthermore, the current collector material can be driven through the passivation layer to form a good electrical connection through the passivation layer. The laser drive in of the metal through the passivation layer can be achieved with a green to infrared laser light. A relatively high pulse power can be used that is absorbed by the metal and the molten metal drives through the passivation layer to make electrical contact with the doped contact below the passivation layer. Furthermore, it is observed that the damage to the silicon material is not significant with respect to performance. In general, reasonable pulse energy densities for this step can be from about 0.5 to about 50 Joules per square centimeter (J/cm²), in further embodiments from about 1.0 to about 40 J/cm² and in other embodiments from about 2.0 to about 25 J/cm². A person of ordinary skill in the art will recognize that additional ranges within these explicit ranges are contemplated and are within the present disclosure. In general, the desired energy density values depend on the thickness of the layers as well as the particular compositions. The general laser-contact approach is described in U.S. Pat. No. 6,982,218 to Preu et al., entitled “Method of Producing a Semiconductor-Metal Contact Through a Dielectric Layer,” incorporated herein by reference.

In some embodiments, to keep any damage to the silicon layer at manageable values, it can be desirable to space apart points of laser drive in of the metal. This is consistent with the objective of forming windows through the passivation layer over an area less than the area of the doped contacts. As with the soft ablation approach, the beam diameter can be made narrower relative to the beam used to form the doped domains so that electrical contact is not made with un-doped, or lightly doped, portions of the silicon. In the resulting laser connection, the metal from the current collector penetrates through the passivation layer to the doped contact below the passivation layer, and the resulting puncture through the passivation layer can be considered a window even though it is not formed without metal penetration. The area of the windows in these embodiments can be estimated from inspection of the resulting laser connections.

The laser contacts can then be formed by pulsing the laser while the beam is scanned across the surface in which the pulse rate is selected to have appropriately spaced apart pulses. Pulse frequencies in some embodiments can be from about 1 kilohertz (kHz) to about 2000 kHz, in further embodiments from about 2 kHz to about 1000 kHz, and in additional embodiments from about 5 kHz to about 200 kHz. Scanning speeds can range in some embodiments from about 0.1 to about 15 meters per second (m/s), and in further embodiments from about 0.25 to about 10 m/s, and in other embodiments from about 1 to about 10 m/s. A person of ordinary skill in the art will recognize that additional ranges of pulse frequencies and scanning speeds within the explicit ranges above are contemplated and are within the present disclosure.

For forming the laser connections, we again define a light spot as a circle along the surface with 95 percent of the light power included within the perimeter. The light pulse rate and scanning speeds can be selected such that the centers of the image of adjacent light pulses are displaced from each other in the range from 1.4 to about 20.0 times the light image diameter, in further embodiments from about 1.5 to about 18.0 times the light image diameter and in additional embodiments from about 1.7 to about 16.0 times the light image diameters. A person of ordinary skill in the art will recognize that additional ranges within the explicit ranges above are contemplated and are within the present disclosure. The processing parameters for laser connection formation can be selected to provide good device performance without an undesirable increase in power loss from series resistance. Surprisingly, with this direct connection approach, the damage to the structure is sufficiently low that very good performance can be achieved.

In general, the current collectors can be formed by any desirable method. However, two desirable methods are described herein for patterning the current collectors. In a first approach, an improved method for patterning of the current collectors comprises forming a multiple layered metal structure and forming an alloy at selected location along the surface. Once the top surface is patterned to form locations with the original top metal or with alloy of the original top metal and the lower metal, a selective etch is performed to remove metal along a selected pattern. Either the original top metal layer is resistant to the etch or the formed alloy combining metal of the two layers is resistant to the etch. The etching step or steps then removes metal along the pattern down to the passivation layer. Thus, the etching process forms a trench in the metal structure to electrically isolate the metal on the opposite sides of the trench.

In general, for the desired processing approach, a plurality of layers of metal are formed in which the top layer is selected to form an alloy with the metal layer under the top layer. In some embodiments, the alloy can be a low melting eutectic alloy. The top metal layer can have a smaller thickness than the lower layer so that a smaller amount of energy is needed to form the alloy as long as the top layer is thick enough to have appropriate structural integrity. In some embodiments, the top layer can have a thickness form about 0.01 to about 0.50, in further embodiments from about 0.02 to about 0.40 and in additional embodiments from about 0.05 to about 0.35 times the thickness of the lower layer of metal. A person of ordinary skill in the art will recognize that additional ranges of thickness ratios within the explicit ranges above are contemplated and are within the present disclosure. Suitable metal combinations include, for example, a nickel or nickel alloy top layer and an aluminum or aluminum alloy bottom layer. Nickel in an alloy with a small amount of vanadium is a suitable material that sputters well. In general, the layers of elemental metal can be deposited, for example, using sputtering, evaporation or other physical vapor deposition approaches or other suitable techniques.

In general, any reasonable energy beam can be used to heat the metal to form the alloy at selected locations along the surface. In particular, an infrared laser beam is a convenient due to relatively good absorption by convenient metals and well as having suitable commercially available infrared lasers at reasonable prices. The patterning for current collectors generally forms contiguous structures that provide for electrical connectivity for the two poles of the cell, and similarly the troughs electrically isolating the opposite poles of the cell need to extend fully along adjacent edges to properly isolate the separate current collectors.

To keep any damage from the alloy formation at suitable levels while forming well defined trenches, it has been found that the use of a lower power energy beam along with multiple passes over the pattern provides excellent results. In general, the pulse energy density can be matched roughly to the properties of the metal including, for example, the thickness of the top metal layer and the melting points of the metals and the resulting alloy. In general, reasonable pulse energy densities can be from about 0.25 to about 25 Joules per square centimeter (J/cm²), in further embodiments from about 0.5 to about 20 J/cm² and in other embodiments from about 1.0 to about 12 J/cm². A person of ordinary skill in the art will recognize that additional ranges of pulse energy densities within the explicit ranges above are contemplated and are within the present disclosure. In some embodiments, it may be desirable to provide two passes, three passes, four passes, five passes or more than five passes of the light beam over the same pattern of the surface to obtain more desirable results.

In general, the line width can be adjusted using the optics to select the corresponding light spot size at least within reasonable values. The line widths of the alloy correspond to the spot size. Pulse frequencies in some embodiments can be from about 5 kilohertz (kHz) to about 5000 kHz, in further embodiments from about 10 kHz to about 2000 kHz, and in additional embodiments from about 25 kHz to about 1000 kHz. Scanning speeds can range in some embodiment from about 0.1 to about 15 meters per second (m/s), and in further embodiments from about 0.25 to about 10 m/s, and in other embodiments from about 1 to about 10 m/s. A person of ordinary skill in the art will recognize that additional ranges of pulse frequencies and scanning speeds within the explicit ranges above are contemplated and are within the present disclosure.

Based on a particular spot size, the scan speed of the light beam across the substrate can be correlated with pulse frequency so that adjacent pulses may overlap to a selected degree to provide a contiguous processed structure with alloy formation. Since the intersection of the light beam with the substrate is generally roughly circular, some overlap can be desirable to get a rough edge of the alloy structure, although multiple passes over the same region can smooth out gaps from adjacent pulses. For convenience, we define a light spot as a circle along the surface with 95 percent of the light power included within the perimeter. The light pulse rate and scanning speeds can be selected such that the centers of the image of adjacent light pulses are displaced from each other in the range from 0.1 to about 1.5 times the light image diameter, in further embodiments from about 0.2 to about 1.25 times the light image diameter and in additional embodiments from about 0.25 to about 1.1 times the light image diameters. A person of ordinary skill in the art will recognize that additional ranges within the explicit ranges above are contemplated and are within the present disclosure.

In general, wet etching and dry etching approaches are known for the selective etching of materials. Wet etching approaches generally involve liquids. The liquids and/or dissolved reactive compositions perform the wet etching through a reaction with the metal. In general, dry etching uses energetic beams, such as plasma or the like to etch a material. For example, halogen ions, such as chlorine, can be used to etch a metal, and inert ions, such as argon ions, can be used to sputter etch a metal. An approach for the selective etching of transition metals is described in U.S. Pat. No. 5,814,238 to Ashby et al., entitled “Method for Dry Etching of Transition Metals,” incorporated herein by reference.

Also, wet etching approaches generally can provide desired amount of etching differential for some reasonable metal layers that can be convenient in some embodiments. A great deal of public information is available relating to wet etchants for metals. In general, wet etchants can comprise acids, bases and/or other reactive compositions. This information can be supplemented by empirical evaluation.

As noted above, the top metal layer is selected to provide an etch resist layer. For an aluminum base layer, suitable top metal layers include, for example, nickel, titanium, molybdenum, and alloys thereof. The aluminum layer and aluminum alloys can be etched with bases, such as KOH and NaOH. Nickel and molybdenum are etched slowly or not at all by hydroxide base etchants, and these metals absorb in the rear IR. More specifically, the etching can be performed with KOH 29% at 80 degrees C. Titanium is etched slowly by KOH. Furthermore, aluminum can be etched with a solution of H₃PO₄:HNO₃:CH₃COOH:H₂O at a weight ratio of 16:1:1:2 at 50° C., and titanium is negligibly etched under these conditions. Therefore, an aluminum or aluminum alloy bottom layer covered with nickel, titanium, molybdenum or alloys thereof form suitable metal layers for the alloy-based patterning approach described herein.

Current collector formation based on alloy formation and selective etching is described further in copending U.S. patent application Ser. No. 12/469,101 filed on the same day as the present application to Srinivasan et al., entitled “Metal Patterning for Electrically Conductive Structures Based on Alloy Formation,” incorporated herein by reference.

In an alternative approach, a soft ablation process can also be used to pattern the metal current collectors. As similarly described above with respect to forming windows through a dielectric layer, a polymer etch resist is deposited on a metal layer, and similar polymer etch resist materials can be used as described above for patterning the dielectric layer. The metal layer can comprise a single metal layer or a plurality of metal layers. A laser is scanned across the surface to ablate the polymer etch resist. The scanning of the pulsed laser can be performed similarly to the scanning to form metal alloy in the alloy based approach. In particular, the dimensions and other parameters of the laser scanning can be similar, except that the laser power may be selected at a lower value and/or a different laser frequency, such as green, blue or ultraviolet, can be selected to ablate the polymer. After ablation of the polymer etch resist at selected locations, the metal can be etched. The metal etching can be performed as described above to form trenches that electrically isolate current collectors of opposite polarity. After etching the metal, the remaining polymer etch resist may or may not be removed depending on the further processing to complete the cell, and if desired just portions of the etch resist can be removed to provide for external electrical connections to the current collectors.

With respect to improving the properties of the contact between the current collector and the doped regions of the semiconductor, a laser anneal step can be performed. In particular, the metal for the current collector can be deposited through windows made through the passivation layer prior to the deposition of the metal. Then, the contact points can be subjected to a laser anneal to improve the contact between the metal and the doped contact. For embodiments in which the current collectors are patterned with polymer etch resist, the laser annealing step can be performed prior to depositing the polymer etch resist or after removal of the remaining polymer etch resist since the anneal sections are distinct from the regions of metal etching. A pulsed laser beam can be scanned across the surface with parameters selected so that the laser beam strikes the locations where the metal is contacting the semiconductor through the windows. The materials can alloy at the interface. This approach can achieve the desired performance of the laser-fired contacts with the use of lower laser power since the dielectric does not need to be pierced during the process step. Thus, the structure can be subjected to less damage and performance can be improved overall.

Generally, the processing steps described herein can be simultaneously performed for an array of cells within a module. During final processing steps to complete a photovoltaic module, electrodes of the solar cells can be connected in series, and other electrical connects can be formed as desired. Also, appropriate electrodes of cells at the end of the series are connected to module terminals. Specifically, once the electrical connections between cells are completed, the external module connections can be formed, and the rear plane of the module can be sealed. A backing layer can be applied to seal the rear of the cell. Since the rear sealing material does not need to be transparent, a range of materials and processes can be used, as discussed above. If a heat sealing film is used, the film is put in place, and the module is heated to moderate temperatures to form the seal without affecting the other components. Then, the module can be mounted into a frame as desired.

### Further Inventive Concepts

In addition to the inventive concepts within the claims below, this application is also directed to the following inventive concepts.

A method for selectively etching openings through an inorganic layer, the method comprising:
patterning a layer of polymeric etch resist by ablating the polymer using an energy beam at a plurality of selected locations to remove the etch resist at the selected locations; and
performing an etch to form windows through the inorganic layer.
   In these embodiments of the method for selectively etching openings, the energy beam can comprise an infrared laser beam. Also, the inorganic layer can comprise a dielectric layer on a semiconductor surface. The inorganic layer can comprise a metal layer. In some embodiments, the method can further comprise removing the remaining polymer etch resist. In addition, the method can further comprise depositing a metal current collector over the remaining polymer etch resist to make electrical contact through the window with a structure below the window wherein the polymer provides electrical insulation.

A method for forming a semiconductor based device, the method comprising:
forming doped domains onto a first surface of a Si semiconductor foil having an average thickness from about 5 microns to about 100 microns wherein the semiconductor foil has a first surface and a second surface opposite the first surface and wherein the second surface of the semiconductor foil is adhered to a glass structure with a polymer;
depositing a dielectric layer onto the first surface covering the doped domains; and
patterning a metal current collector on the dielectric layer wherein portions of the metal current collector make contacts with the doped domains through the dielectric layer,
wherein the processing steps do not heat the polymer to a temperature greater than about 200° C.

A photovoltaic cell comprising a semiconductor layer, an n-doped domain and a p-doped domain along a surface of the semiconductor layer wherein the doped domains each have a planar extent along the surface comprising a stripe having a ratio of the average length that is at least about a factor of 10 greater than the average width wherein one or more enhanced dopant sections of the stripe have an average surface dopant concentration that is at least about 5 times the average dopant concentration at other locations of the n-doped domain. In these embodiments of the photovoltaic cell, the enhanced dopant section of the stripe may cover no more than about 50 percent of the area of the stripe. Also, the enhanced dopant sections can comprise the center of the stripe.

A photovoltaic cell comprising a semiconductor layer, a plurality of n-doped domains and a plurality of p-doped domains along a surface of the semiconductor layer wherein the doped domains have an average depth from about 250 nm to about 2.5 microns and wherein the top 10% of the thickness of the contact have an average dopant concentration that is at least a factor of 5 greater than the average dopant concentration for the contact at the level at the 20-30% of the doped contact depth from the top of the contact.

A photovoltaic cell comprising a semiconductor layer, a plurality of n-doped domains along a surface of the semiconductor layer, a plurality of p-doped domains along the surface of the semiconductor layer, a dielectric layer, a first current collector in electrical connection with the n-doped domains, and a second current collector in electrical contact with the p-doped domains, wherein the dielectric layer comprises an inorganic layer along the surface of the semiconductor layer and a polymer layer on the inorganic layer with the current collectors covering a portion of the polymer layer and wherein the respective current collectors contact the corresponding doped domain through windows through the dielectric layer.

A method for doping a semiconductor layer, the method comprising:
patterning a plurality of dopant sources along a bare semiconductor layer comprising silicon/germanium to form a patterned semiconductor layer; and
scanning a light beam across the patterned semiconductor layer to drive dopant from the dopant sources into the semiconductor layer to form a plurality of n-doped domains and a plurality of p-doped domains.

A method for forming electrical connections within a solar cell, the method comprising:

laser annealing a location of a metal current collector with a semiconductor at a location where the metal contacts the semiconductor through a window through a dielectric layer.

### EXAMPLES

### Example 1

### Creation of N-Type and P-Type Silicon by Laser Annealing

This example describes a method for creating n-type and p-type regions in a silicon wafer by laser annealing.

Commercially obtained single crystal CZ silicon wafers were initially cleaned/etched with HF to remove silicon oxide along the surface. The wafers were 4 inch diameter n-doped CZ wafers with a resistivity of 5-10 ohm-cm. A coating of doped spin-on-glass was applied by spin coating to the clean wafer surfaces. Suitable spin-on-glass materials are available from Filmtronics and Honeywell. The coated wafer was then heated at 150° C. for fifteen minutes to dry the material.

It was found that the thickness of the spin-on glass could be reduced by increasing the spin speed. Thicknesses between 50 nm and 2 microns could be obtained through the selection of the spin-on-glass material and the spin speed. The thickness was measured using a profilometer. Thickness measurements are summarized in Table 1.

TABLE 1

| | | Baking | | |
|---|---|---|---|---|
| | | Temp | Center | |
| Sample | | for | Thickness | Edge Thickness |
| ID | RPM | 15 min | (nm) | (nm) |
| D113 | 3000 | 150° C. | 540 | 543 |
| D119 | 5500 | 150° C. | 295 | 299 |
| D118 | 8000 | 150° C. | 274 | 265 |

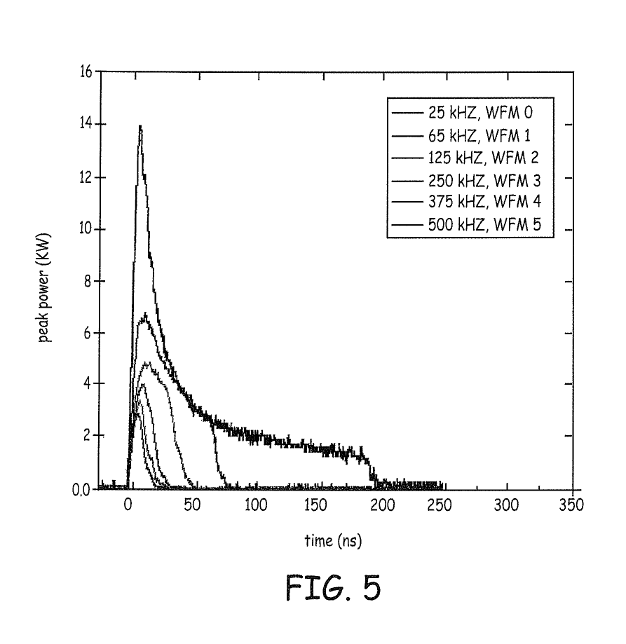

Doped regions were then created in the wafer by laser doping. The annealing process was performed by scanning a pulsed infrared laser beam across the surface of the wafer and annealing the silicon at locations where the laser beam contacted the surface. The scanning system used a ScanLabs Galvo™ scanner to direct the beam to the surface. A 20 watt diode pumped fiber laser (SPI Lasers, UK) with a center wavelength of 1064 nm was used to generate the laser beam. At locations where the laser contacted the surface, the silicon was melted, and dopant was driven into the wafer. The dopant drive-in was performed with different laser pulse rates and different laser waveforms. The laser response for the different waveforms is shown in FIG. 5. After performing the laser dopant drive in, the spin on dopant material was removed using methanol, and the surfaces were cleaned with a mixture of sulphuric acid and hydrogen peroxide.

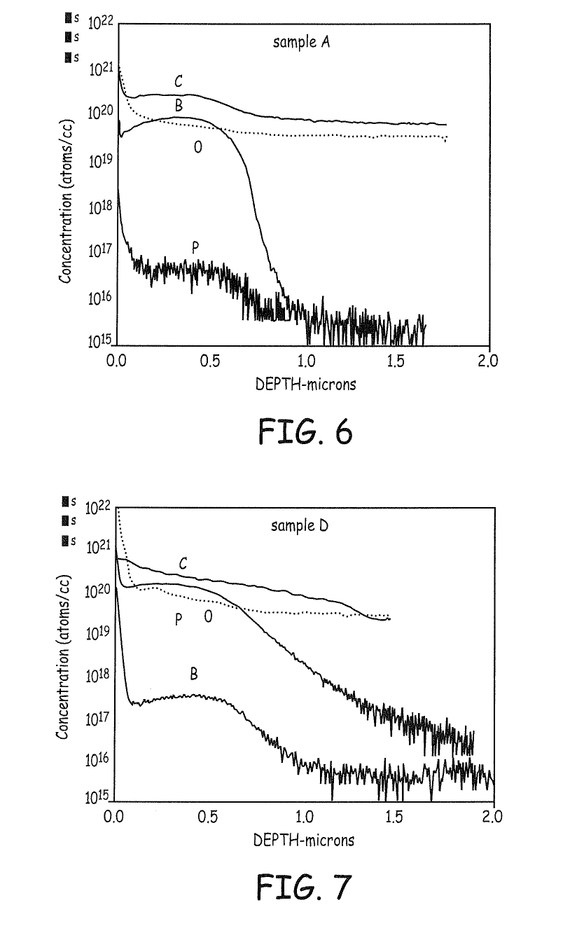

Secondary Ion Mass Spectroscopy (SIMS) measurements with sputtering were performed to measure the depth and profile of dopant within the doped contacts formed using the laser drive-in. SIMS measurements are shown in FIG. 6 for p-doped contacts on a wafer with light n-doping and in FIG. 7 for n-doped contacts on a wafer with light p-doping, which are both formed with a laser pulse energy of 2.31 J/cm² with a laser scanning speed of 0.5 meters per second (m/s) and with a laser pulse frequency of 500 kHz. As shown in FIG. 6, the phosphorous dopant from the original wafer has a moderate concentration enhancement for roughly 1 micron at the wafer surface. The added boron dopant has a relatively high concentration for roughly 600-700 nm into the wafer with a gradual drop then to the background level at about 1 micron. Carbon and oxygen contaminants have a slight elevation near the wafer surface. Referring to FIG. 7, the boron dopant in the wafer material shows a similar moderate enhancement from the background concentration in the top micron of the wafer. The added phosphorous dopant has a relatively flat value for about 600 nm into the wafer that is followed with a gradual decrease in concentration to about 2 microns into the wafer.

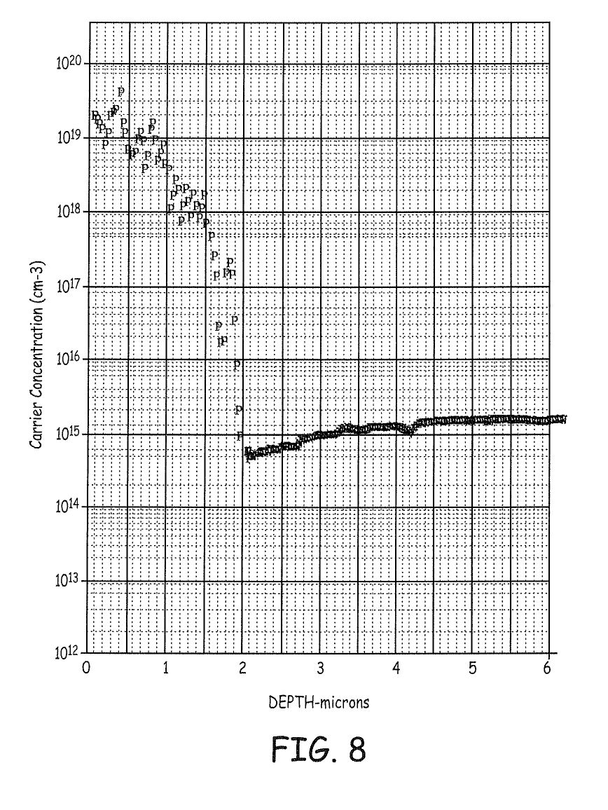

Dopant depth was also measured with Spreading Resistance Profiling (SRP) for a P-doped contact. A four probe resistivity measurement was made on a beveled sample by Solecon Laboratories, Nevada, U.S. The results of these measurements are shown in FIG. 8. The results in FIG. 8 are similar to the results in FIG. 7 except that the values are somewhat lower in the SRP measurements relative to the SIMS measurements and that there is no spike in the SIMS measurements at the immediate surface.

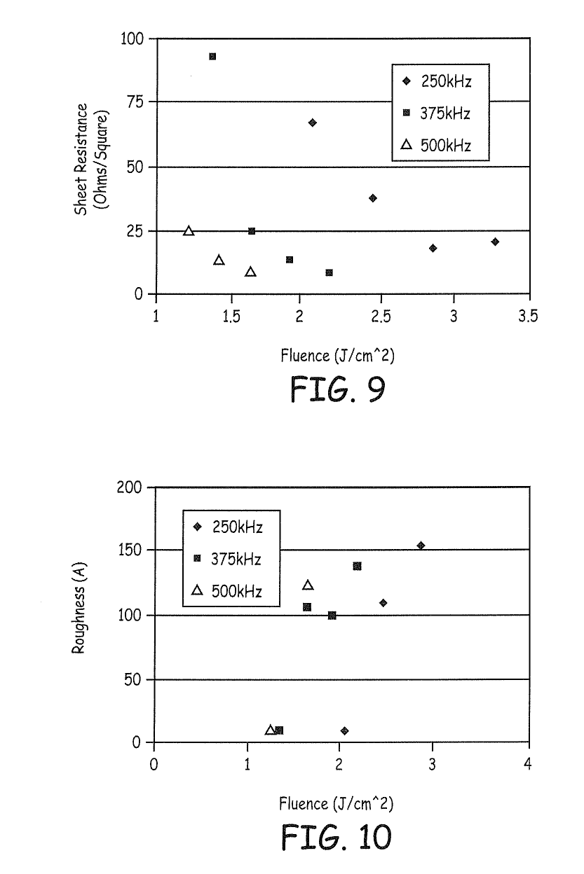

In addition, the sheet resistance was measured for a P-doped region after laser doping. The sample was beveled at an angle, and the four probe sheet resistance was measured. The sheet resistance results in ohms per square are shown in FIG. 9 for three different laser pulse frequencies over a range of laser fluences. Sheet resistance was generally lower with higher laser fluences and with higher laser frequencies. The surface roughness in angstroms was also measured for the doped contacts with different laser pulse frequencies and different laser fluences. The surface roughness was measured using a Tencor stylus profilometer (KLA Tencor Instruments). The results are plotted in FIG. 10. Lower laser fluences resulted in a smoother surface with a significant dependence on laser frequency.

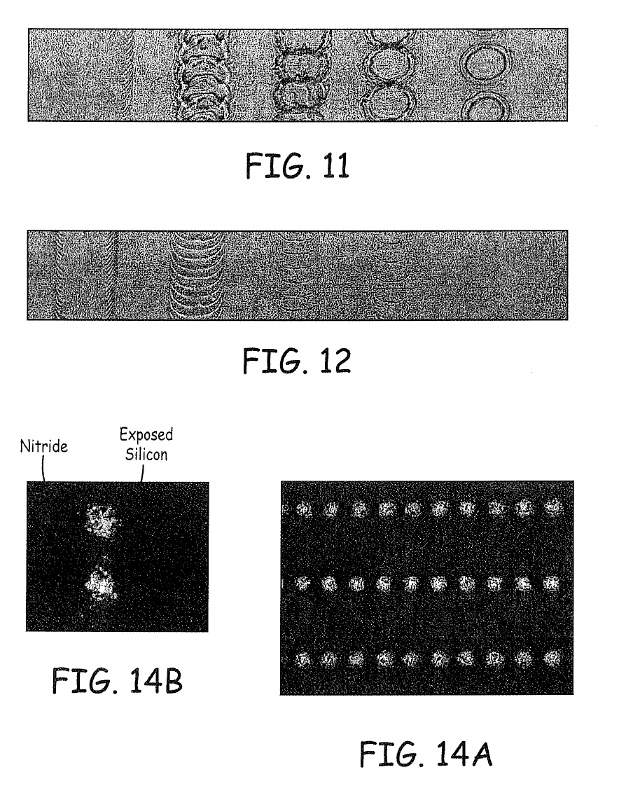

Photographs of the substrate surface after the laser dopant drive in are shown for five scanning speeds in FIG. 11 for a laser fluence of 6.11 J/cm² and a laser pulse frequency of 125 kHz and in FIG. 12 for a laser fluence of 3.06 J/cm² and a laser pulse frequency of 250 kHz. In each of these figures, from left to right, the scanning speeds were 1 m/s, 2 m/s, 3 m/s, 4 m/s and 5 m/s.

Based on the experiments, it was found that an increased laser power level resulted in increased dopant depth and a correspondingly deeper molten region leading to better dopant homogeneity. Increasing the laser scan speed results in reduced laser spot overlap while increasing the laser pulse frequency leads to greater spot overlap, a lower dopant depth due to a lower peak laser power and likely dopant in-homogeneity.

### Example 2

### Window Patterning Through Dielectric Layer Using Polymer Ablation

This example describes the patterning of an inorganic dielectric layer using laser ablation of a polymer etch resist.

The substrate was prepared by depositing either a silicon nitride or a silicon oxide coating onto a silicon wafer containing both n-type and p-type regions as prepared by the method described in Example 1. PECVD was used to deposit the silicon nitride or silicon oxide coating on the side of the wafer with patterned doped domains. To deposit silicon oxide, nitrous oxide and silane gases were pumped into a 650 milliTorr reaction chamber at 1400 sccm and 400 sccm, respectively. The plasma was created in the reaction chamber with radio frequency excitation at 40 W. The thickness can be evaluated using the deposition conditions and verified using scanning electron microscopy. The silicon nitride layer was deposited using PECVD with NH₃ as a replacement for N₂O reactant. The silicon nitride coatings had an average thickness of about 65 nm and the silicon oxide coatings had an average thickness of about 500 nm.

A layer of dissolved polymer etch resist, Fujifilm OIR 900 series Photoresist, was deposited using spin coating. The solvent was removed by drying, and the resulting polymer coating had a thickness of about 1 micron. A pulsed laser was scanned across the surface as described in Example 1 to ablate the polymer at selected spots along the surface. The laser was scanned at a rate of 1 m/s at a fluence of 6.11 J/cm² and a pulse frequency of 65 kHz. After the polymer etch resist was ablated, the surface was etched to remove the inorganic dielectric to expose the silicon at the etched locations. The silicon oxide is etched at room temperature using buffered HF that was formed as a 6:1 volume ratio of 40% NH₄F in water to 49% HF in water. Silicon nitride was siuilarly etched using HF. The polymer was then removed using an organic solvent.

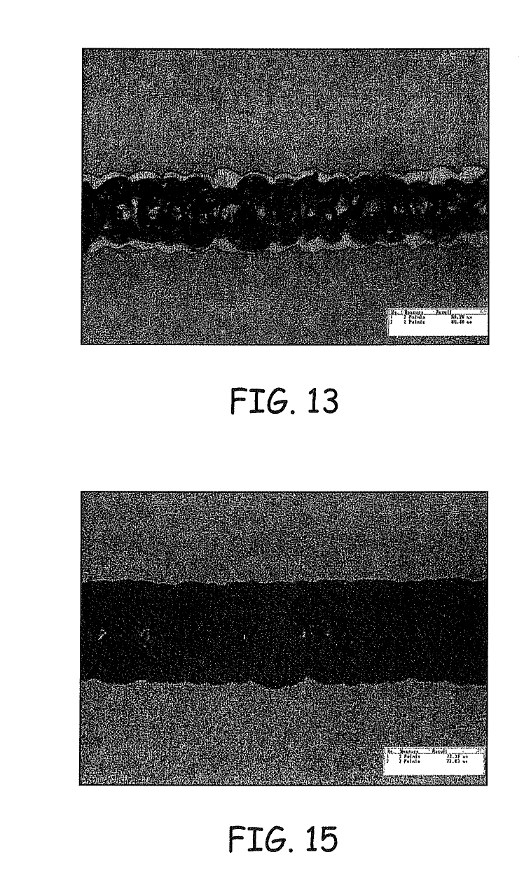

A photograph of a line etched through a silicon oxide layer following etching patterned with polymer etch resist is shown in FIG. 13. Similar results were obtained with either silicon oxide or silicon nitride dielectric layers.

### Example 3

### Ablation of Dielectric Layer for Window Patterning

This example demonstrates patterning of a dielectric layer using laser ablation in which the laser parameters are selected to form windows through the dielectric layer without significantly damaging the underlying silicon layer.

The substrate was prepared by depositing a silicon nitride onto a patterned doped silicon wafer as described in Example 2. A pulsed laser was scanned across the surface as described in Example 1 to ablate the silicon nitride at selected spots along the surface. A photograph of a wafer surface after ablation of holes through the silicon nitride layer is shown in FIG. 14A. A close up is shown in FIG. 14B, in which exposed silicon is visible below the silicon nitride dielectric layer. An examination of the wafer confirmed that the silicon at the location of the windows was not significantly damaged.

### Example 4

### Metal Patterning Based on Ablation of Polymer Etch Resist

This example demonstrates that laser ablation of polymer etch resist can also be used to pattern aluminum for the formation of a current collector.

The wafer was prepared with a silicon oxide coating as described in Example 2. An aluminum layer with an average thickness of about 1 micron was sputtered onto the silicon oxide coating. The sputtering process was performed using a Perkin Elmer 4450 sputtering system (Perkin Elmer, Waltham, Mass.) in which an inert carrier gas was ionized and accelerated by an electric field to the metal target, which was either an aluminum metal target or nickel alloy target The sputtering resulted in the relatively uniform deposition of metal onto silicon oxide layer on the wafer surface. The sputtering process was performed with an aluminum target.

The polymer etch resist was applied as described in Example 2. A pulsed infrared laser was scanned as described in Example 1 across the surface to ablate the polymer at selected spots along the surface. The laser was scanned at a rate of 1 m/s at a fluence of 6.11 J/cm² and a pulse frequency of 65 kHz. After the polymer etch resist was ablated at the selected locations of the laser scan, the surface was etched to remove aluminum at the location where the polymer was removed. The aluminum was etched with a mixture of phosphoric acid, nitric acid and acetic acid. The polymer was removed with an organic solvent after etching the aluminum. A photograph of a line etched through the aluminum is shown in FIG. 15 where dielectric is visible through the aluminum. Thus, the laser ablation of a polymer etch resist was successfully used to pattern a metal current collector.

### Example 5

### Metal Patterning Based on Alloy Formation

This example describes a non-photolithographic process for patterning shapes in a metal layered structure on a silicon substrate covered with a dielectric layer.

The substrate was prepared by initially depositing a silicon nitride coating onto a commercial single crystalline silicon wafer using PECVD as described in Example 2. The resulting silicon nitride layer was 65 nm thick. The thickness was evaluated using the deposition conditions and verified using scanning electron microscopy.

Aluminum and nickel-alloy layers were subsequently deposited on the dielectric coated surface of the wafer using sputtering. The sputtering process was performed using a Perkin Elmer 4450 sputtering system (Perkin Elmer, Waltham, Mass.) in which an inert carrier gas was ionized and accelerated by an electric field to an aluminum metal target The sputtering resulted in the relatively uniform deposition of aluminum metal onto the silicon nitride surface. The sputtering process was then repeated using a metal target comprising nickel alloy with 7% vanadium, again resulting in a relatively uniform deposition. The resulting aluminum layer was 1 μm thick, and the resulting nickel layer was 150 nm thick.

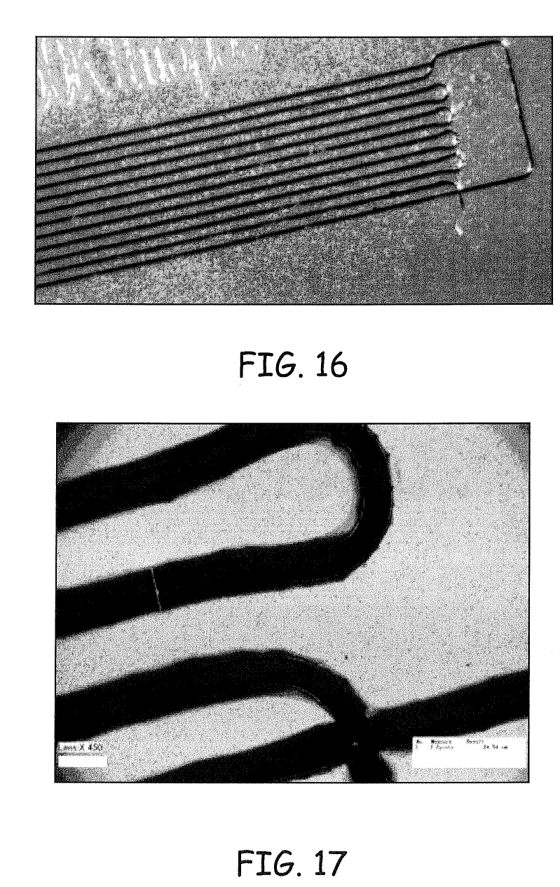

The substrate with the two metal layers was patterned by sweeping a laser beam in across the surface to generate an aluminum-nickel alloy at the locations where the laser beam contacts the surface. The scanning system used a 20 watt diode pumped fiber laser (SPI Lasers, UK) with a center wavelength of 1064 nm to generate the laser beam. The infrared light from the laser beam was used to heat the substrate's surface and form the alloy. It has been found that the use of a lower laser power and multiple passes of the scanned laser over the same pattern results in improved formation of alloy along a pattern with lines and curves while obtaining less damage to the structure under the metal. Also, it has been found that with commercial scanners, turns formed with multiple linear segments joined with modest angular changes results in improved structures relative to scanning along curves. The peak power of the pulse was reduced by operating the laser at 60% power at a 250 KHz repetition rate. The peak power and fluence levels were 1.92 KW and 2.44 J/cm², respectively. The laser was rastered across the substrate's surface with a ScanLab Galvo scanner (ScanLab America, Inc., Naperville, Ill.) at 3 m/s. The substrate was patterned with the laser rastering three times over the same pattern prior to etching. A representative pattern is shown in FIG. 16, which has an area of roughly 1 square centimeter.

The aluminum-nickel alloy and the aluminum below the alloy were then etched with KOH, leaving only the unalloyed nickel covered aluminum. The etching process was performed by placing the substrate in a bath of 25% KOH for about 3 minutes. The bath was maintained at 40 C and the concentration gradient of the solution was reduced by either stirring or gas bubbling. FIG. 17 shows clean etching in the straight segments, the u-turn segments, and the intersection. The nickel covered aluminum sections were electrically isolated, and there were no shunted paths or damage to the underlying silicon nitride layer.

### Example 6

### Solar Cell Device Performance with Deep Doped Domains Formed by Bare Silicon Laser Drive-In Along Stripes

This example describes specific embodiments of overall solar cell structures and the resulting performance where deep doped domains are formed by driving the dopant into the silicon material with an infrared laser scanned along stripes.

In a first version, single crystal wafers were cut to a thickness of 200 microns. Emitters (n-doped domains) and collectors (p-doped domains) were patterned along a surface of the wafer using the infrared laser drive in as described in Example 1. The different dopants were sequentially applied with a cleaning of the surface after each dopant drive in step. PECVD was used to apply a 70 nm SiNₓ (silicon rich silicon nitride) coating onto the sun-side (un-doped side) of the wafer and a 65 nm SiN, coating onto the doped side (device side) of the wafer. The silicon nitride on the device side of the wafer was patterned with 15 micron wide stripes using photolithography. A two micron thick layer of aluminum metal was sputter coated onto the patterned silicon nitride dielectric layer as described above in Example 3. The metal was patterned with interdigitated stripes into two collectors using photolithography with one current collector joining the n-doped domains and a second current collector joining the p-doped domains.

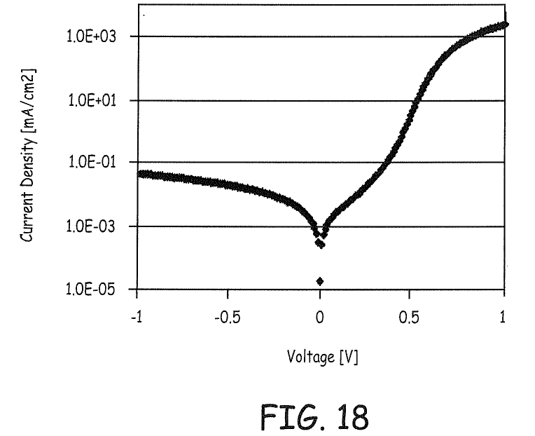

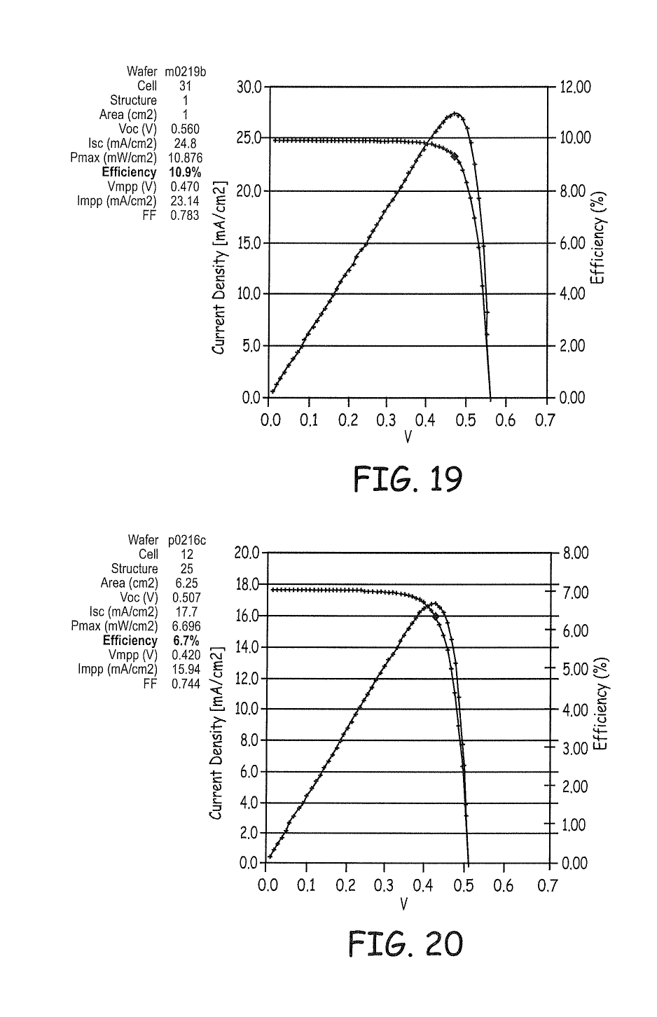

The resulting solar cell was tested under one sun conditions using a Newport Sun Simulator (Newport Corporation, Calif., USA). The diode performance without illumination is plotted in FIG. 18. The performance under 1 sun conditions is plotted in FIG. 19. The cell had an open circuit voltage of 0.560 volts and an efficiency of 10.9%. The cell was also characterized by I_{sc}, the short circuit current, and FF, the fill factor.

Another sample was prepared with 50 micron thick single crystalline silicon laminated with an adhesive onto glass. The silicon was prepared using lapping and chemical mechanical polishing. The n-doped bases were formed in stripes with a 150 micron width, and the p-doped emitters were formed in stripes with a 50 micron width. The stripes of the base and emitters were separated by 150 microns. A 65 nm SiNₓ dielectric layer was applied with PECVD to the sun side of the wafer before laminating the silicon to the glass. A 65 nm SiNₓ dielectric layer was applied using PECVD at a temperature below 300° C. to the device side of the wafer after laminating the wafer to the glass. Then, a 200 nm silicon oxide layer was sputtered over the silicon nitride layer. The dielectric layers were patterned using photolithography to form windows as 15 micron wide stripes through the silicon oxide and silicon nitride layers to exposed portions of the doped contacts. A 2 micron thick layer of aluminum was deposited over the patterned dielectric, and the aluminum was patterned into two current collectors using photolithography. One current collector connected the n-doped domains and the other current collector connected the p-doped domains with a 150 micron pitch between the current collectors.

The device had an area of 6.25 cm². The device was tested under one sun conditions. The performance of the cell is shown in FIG. 20. The cell had an efficiency of 6.7% and an open circuit voltage of 0.507 volts.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A photovoltaic cell comprising a semiconductor layer, an n-doped domain and a p-doped domain along a surface of the semiconductor layer at the same level as each other wherein the doped domains each have an average depth from about 100 nm to about 5 microns and an edge-to-edge spacing between the n-doped domain and the p-doped domain has a value at one or more locations from about 5 microns and about 500 microns.

2. The photovoltaic cell of claim 1 wherein the semiconductor layer comprises elemental silicon/germanium.

3. The photovoltaic cell of claim 2 wherein the elemental silicon/germanium comprises an n-type dopant or p-type dopant at a concentration from about 1×10¹⁴ to about 1×10¹⁶ atoms per cubic centimeter.

4. The photovoltaic cell of claim 1 wherein the semiconductor layer has an average thickness form about 5 microns to about 300 microns.

5. The photovoltaic cell of claim 1 wherein the doped domains have an average depth from about 250 nm to about 2.5 microns.

6. The photovoltaic cell of claim 1 wherein the spacing between the n-doped domain and the adjacent p-doped domains has a value at one or more locations from about 20 microns to about 200 microns.

7. The photovoltaic cell of claim 1 wherein the doped domains have an average dopant concentration from about 1.0×10¹⁸ to about 5×10²⁰.

8. A photovoltaic cell comprising a semiconductor layer, an n-doped domain and a p-doped domain along a surface of the semiconductor layer at the same level as each other wherein the doped domains each have a planar extent along the surface comprising a stripe having a ratio of the average length that is at least about a factor of 10 greater than the average width and a spacing between the n-doped domain and the p-doped domain has a value at one or more locations from about 10 microns and about 500 microns.

9. The photovoltaic cell of claim 8 wherein each of the doped domains have a planar extent along the surface comprising a stripe having a ratio of the average length that is at least a factor of 15 greater than the average width.

10. A photovoltaic cell comprising a semiconductor layer, an n-doped domain and a p-doped domain along a surface of the semiconductor layer wherein the doped domains each have a planar extent along the surface comprising a stripe having a ratio of the average length that is at least about a factor of 10 greater than the average width, a dielectric layer over the doped domains and a plurality of patterned metal interconnects, wherein the dielectric layer comprises windows that expose from about 5 percent to about 80 percent of each of the doped domains and wherein the metal interconnects over the windows with the metal interconnects have an area at least about 20 percent greater than the area of the windows.

11. The photovoltaic cell of claim 10 wherein the windows expose from about 10 percent to about 70 percent of each of the doped domains.

12. The photovoltaic cell of claim 10 wherein the metal interconnects over the windows with the metal interconnects having an area at least about 100 percent greater than the area of the windows.

13. A method for doping a semiconductor along a selected pattern, the method comprising:
pulsing an energy beam at a plurality of selected locations along a surface to drive a first dopant from a dopant source into a semiconductor layer at the selected location to form a first doped domain wherein the dopant source is formed in a layer substantially covering the semiconductor layer;
removing the first dopant source;
depositing a second dopant source comprising a second dopant to substantially cover the semiconductor layer; and
pulsing an energy beam at a plurality of selected locations along a surface to drive the second dopant into a semiconductor layer at the selected location to form a second doped domain.

14. The method of claim 13 wherein the energy beam comprises an infrared laser.

15. The method of claim 14 wherein the dopant is driven down to a depth from about 100 mu to about 5 microns.

16. The method of claim 13 wherein the first doped domain comprises a stripe having a ratio of the average length that is at least about a factor of 10 greater than the average width.
